(19) United States
(12) Patent Application Publication
(10) Pub. No.: US 2025/0391705 A1
(43) Pub. Date: Dec. 25, 2025

(54) SEMICONDUCTOR DIE PACKAGES AND METHODS OF FORMATION

(71) Applicant: Taiwan Semiconductor Manufacturing Company, Ltd., Hsinchu (TW)

(72) Inventors: Harry-HakLay CHUANG, Zhubei City (TW); Wen-Tuo HUANG, Tainan City (TW); Wei-Cheng WU, Zhubei City (TW); Yu-Ling HSU, Tainan City (TW); Yu-Chun CHANG, Tainan City (TW); ShihKuang YANG, Tainan City (TW); Pai Chi CHOU, Taichung City (TW); Che-Wei CHEN, Taichung City (TW)

(21) Appl. No.: 18/748,549

(22) Filed: Jun. 20, 2024

(51) Int. Cl. H01L 21/768; H01L 21/02; H01L 23/00; H01L 23/48; H01L 25/16

(52) U.S. Cl. CPC H01L 21/76898; H01L 21/02112; H01L 23/481; H01L 24/08; H01L 25/162; H01L 2224/08146

(57) ABSTRACT

High dielectric constant (high-k) passivation layers are omitted from a back side surface of a device layer of a semiconductor die in a semiconductor die package. Instead, a hard mask layer is formed directly on the back side surface of the device layer, and the hard mask layer is patterned and used to form one or more elongated conductive structures (e.g., one or more through substrate vias (TSVs)) through the device layer. The high-k passivation layers may be omitted for particular types of device layers and/or for particular types of integrated circuit devices, thereby reducing the complexity, time, and cost for forming the semiconductor die package.

### BACKGROUND

Various semiconductor device packing techniques may be used to incorporate one or more semiconductor dies into a semiconductor die package. In some cases, semiconductor dies may be horizontally interconnected through an interposer. Additionally and/or alternatively, semiconductor dies may be arranged vertically in a semiconductor die package to achieve a smaller horizontal or lateral footprint of the semiconductor die package and/or to increase the density of the semiconductor die package. The semiconductor dies may be connected directly through die-to-die (or wafer-to-wafer) bonding and/or through interconnects and one or more interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor die package described herein.

FIGS. 2A-2D are diagrams of an example implementation of forming a semiconductor die described herein.

FIGS. 3A and 3B are diagrams of an example implementation of forming a semiconductor die package described herein.

FIGS. 4A-4J are diagrams of an example implementation of forming an elongated conductive structure described herein.

FIG. 5 is a diagram of an example semiconductor die package described herein.

FIGS. 6A-6J are diagrams of an example implementation of forming an elongated conductive structure described herein.

FIG. 7 is a flowchart of an example process associated with forming a semiconductor die package described herein.

FIG. 8 is a flowchart of an example process associated with forming a semiconductor die package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor die in a semiconductor die package may be connected to interconnect layers on both sides of the semiconductor die. For example, a first interconnect layer may be included on a first side (e.g., a front side) of the semiconductor die, and a second interconnect layer may be included on a second side (e.g., a back side) of the semiconductor die opposing the first die. In some cases, the first interconnect layer may be used for routing signals throughout the semiconductor die, and the second interconnect layer may be used for providing power to the integrated circuit devices of the semiconductor die. Additionally and/or alternatively, one of the first or second interconnect layers may be bonded to another semiconductor die and may be used for inter-die communication, and the other interconnect layer may be connected to the connector of the semiconductor die package for making external connections.

To enable signals and/or power to be routed between the first and second interconnect layers, one or more elongated conductive structures may be included through a device layer (e.g., a semiconductor layer or semiconductor substrate) in which the integrated circuit devices are included. The elongated conductive structure(s) (sometimes referred to as through silicon vias or through substrate vias (TSVs)) connect with one or more metallization layers in the first and second interconnect layers, and may be formed of electrically conductive metals such as copper (Cu) to achieve a low electrical resistance between the metallization layers in the first and second interconnect layers through the elongated conductive structure(s).

A wafer grinding operation may be performed on the back side of the device layer to reduce the thickness of the device layer in preparation for forming the elongated conductive structure(s) through the device layer. The wafer grinding operation may cause damage to the back side surface of the device layer, resulting in the formation of dangling bonds that can cause current leakage for the integrated circuit devices formed in the device layer, particular for active integrated circuit devices such as transistors. Thus, one or more high dielectric constant (high-k) dielectric passivation layers may be formed on the back side of the device layer to passivate the damage (e.g., to passivate the charge-trapping centers resulting from the dangling bonds), resulting in increased complexity, time, and cost for forming the semiconductor die package.

In some implementations, high-k passivation layers are omitted from a back side surface of a device layer of a semiconductor die in a semiconductor die package. Instead, a hard mask layer is formed directly on the back side surface of the device layer, and the hard mask layer is patterned and used to form one or more elongated conductive structures (e.g., one or more TSVs) through the device layer. The high-k passivation layers may be omitted for particular types of device layers and/or for particular types of integrated circuit devices, thereby reducing the complexity, time, and cost for forming the semiconductor die package, without (or with minimal) reduction in semiconductor die package manufacturing yield. For example, the hard mask layer may be formed directly on the back side surface of the device layer without the use of high-k passivation layers in semiconductor dies that include integrated circuit devices that are not (or a minimally) susceptible to current leakage. Such integrated circuit devices may include passive integrated circuit devices such as resistors, capacitors, and/or inductors, among other examples. As another example, the hard mask layer may be formed directly on the back side surface of the device layer without the use of high-k passivation layers in semiconductor dies in which a buried (or integrated) isolation layer is included between semiconductor layers in the device layer. The buried isolation layer provides electrical isolation for the integrated circuit devices in a first semiconductor layer of the device layer, and protects the integrated circuit devices from dangling bonds that might have formed during a wafer grinding operation to reduce the thickness of a second semiconductor layer of the device layer.

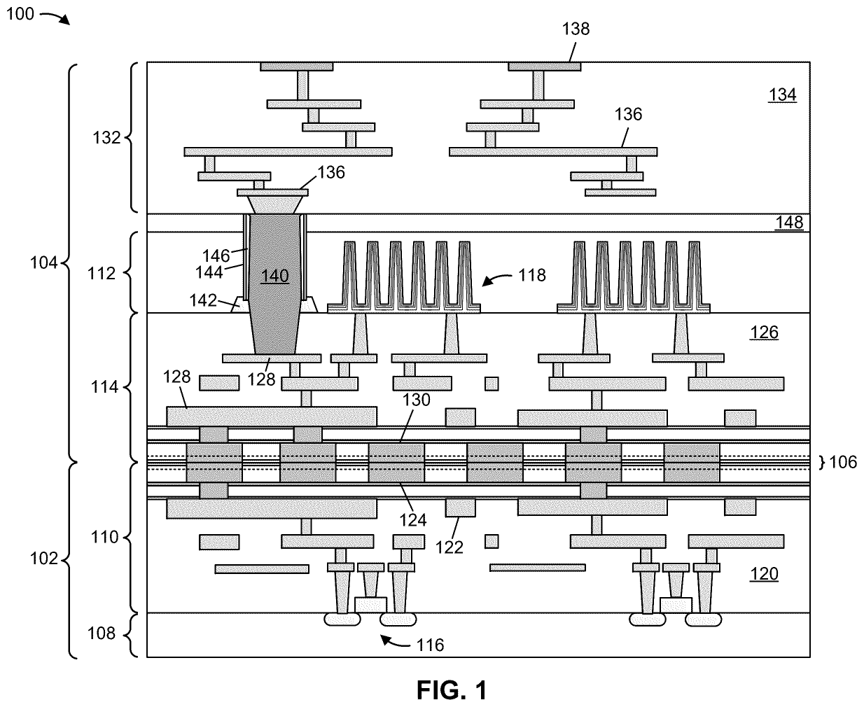

FIG. 1 is a diagram of an example semiconductor die package 100 described herein. FIG. 1 illustrates a cross-section view of the semiconductor die package 100. As shown in FIG. 1, the semiconductor die package 100 includes a semiconductor die 102 and a semiconductor die 104 bonded at a bonding interface 106 such that the semiconductor dies 102 and 104 are stacked and vertically arranged in the semiconductor die package 100. The bond between the semiconductor dies 102 and 104 may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor dies 102 and 104 by forming metal-to-metal bonds and/or dielectric-to-dielectric bonds at the bonding interface 106 between the semiconductor dies 102 and 104.

The semiconductor die 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor die 102 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The semiconductor die 104 may include the same type of semiconductor die as the semiconductor die 102, or may include a different type of semiconductor die.

As further shown in FIG. 1, the semiconductor die 102 may include a device layer 108 and an interconnect layer 110 above the device layer 108. The semiconductor die 104 may include a device layer 112 and an interconnect layer 114 below the device layer 112. The bonding interface 106 may be located between the interconnect layers 110 and 114, and may include portions of each of the interconnect layers 110 and 114. The bonding interface 106 may include conductive structures of the interconnect layers 110 and 114 that are bonded together by metal-to-metal bonds, and/or dielectric layers of the interconnect layers 110 and 114 that are bonded together by dielectric-to-dielectric bonds.

The device layer 108 may correspond to a portion of a semiconductor wafer on which the semiconductor die 102 was formed, and the device layer 112 may correspond to a portion of another semiconductor wafer on which the semiconductor die 104 was formed. The device layers 108 and 112 may each include a silicon (Si) substrate, a substrate formed of a material including silicon, a III-V compound semiconductor material substrate such as gallium arsenide (GaAs), a silicon on insulator (SOI) substrate, or another type of semiconductor substrate.

The semiconductor die 102 may include integrated circuit devices above the substrate of the device layer 108 and in the interconnect layer 110. The integrated circuit devices 116 may include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of passive and/or active integrated circuit devices.

The semiconductor die 104 may include integrated circuit devices 118 in the substrate of the device layer 112. The integrated circuit devices 118 include passive integrated circuit devices such as capacitors (e.g., metal-insulator-metal (MIM) capacitors, deep trench capacitors (DTCs)), resistors, and/or inductors, among other examples. In particular, the semiconductor die 104 may include a semiconductor die that includes only passive integrated circuit devices in the device layer 112. For example, the semiconductor die 104 may be a DTC die, an inductor-capacitor die (LC die), and/or another type of semiconductor that includes only passive integrated circuit devices. In some implementations, the integrated circuit devices 118 (e.g., inductors, capacitors) of the semiconductor die 104 are electrically connected with the integrated circuit devices 116 (e.g., active integrated circuit devices such as transistors) of the semiconductor die 102 to form a voltage regulator circuit of the semiconductor die package 100. In some implementations, the integrated circuit devices 118 include decoupling trench capacitors, that provide noise decoupling by shunting noise (e.g., voltage spikes, voltage swings) for the integrated circuit devices 116 of the semiconductor die 102.

The interconnect layers 110 and 114 may each include conductive structures that interconnect the integrated circuit devices 116 and 118 of the device layers 108 and 112, respectively. Additionally and/or alternatively, the interconnect layers 110 and 114 may each include conductive structures that electrically connect the semiconductor dies 102 and 104.

The interconnect layer 110 of the semiconductor die 102 includes one or more dielectric layers 120 that are arranged in a direction that is approximately perpendicular to the device layer 108. The dielectric layer(s) 120 may include backend dielectric layers (e.g., interlayer dielectric (ILD) layers, intermetal dielectric (IMD) layers) and etch stop layers (ESLs) that are arranged in an alternating manner in the interconnect layer 110. The dielectric layer(s) 120 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 110 includes a plurality of conductive structures 122 (e.g., electrically conductive structures) in the dielectric layer(s) 120. The conductive structures 122 are electrically coupled and/or physically coupled with one or more of the integrated circuit devices 116 in the device layer 108, and are electrically interconnected together in the interconnect layer 110. The conductive structures 122 correspond to circuit routing that enables signals and/or power to be provided to and/or from the integrated circuit devices 116. The conductive structures 122 may include a combination of conductive structures that extend primarily horizontally in the interconnect layer 110 (e.g., trenches, conductive lines) and that are interconnected by interconnect structures (e.g., vias) that extend primarily vertically in the interconnect layer 110. The conductive structures 122 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer 110 may be arranged in a vertical manner to facilitate electrical signals and/or power to be routed between the device layer 108 and the semiconductor die 104, between integrated circuit devices 116 through the interconnect layer 110, and/or between the integrated circuit devices 116 and the integrated circuit devices 118 in the semiconductor die 104. The conductive structures 122 may be arranged in alternating layers of metallization layers (referred to as “M”-layers) and via layers (referred to as “V”-layers). Each metallization layer may include one or more conductive structures laterally arranged in the interconnect layer 110, and each via layer may include one or more interconnect structures that interconnect the metallization layers in the interconnect layer 110. As an example, a metal-0 (M0) layer may be located at the bottom of the interconnect layer 110 and may be coupled with the integrated circuit devices 116 in the device layer 108, a via-1 (V1) layer may be located above and coupled with a contact layer in the interconnect layer 110, a metal-1 layer (M1) layer may be located above and coupled with the V1 layer in the interconnect layer 110, a via-2 (V2) layer may be located above and coupled with the M1 layer in the interconnect layer 110, a metal-2 layer (M2) layer may be located above and electrically coupled with the V2 layer in the interconnect layer 110, and so on. In some implementations, the interconnect layer 110 includes eight (8) stacked metallization layers (e.g., M1-M8). In some implementations, the interconnect layer 110 includes another quantity of stacked metallization layers.

At the bonding interface 106, the interconnect layer 110 may include a plurality of bonding pads 124. The bonding pads 124 may be electrically coupled with the conductive structures 122 in the interconnect layer 110 by bonding vias and/or other types of conductive structures. The bonding pads 124 may each include tungsten (W), cobalt (Co), ruthenium (Ru), titanium (Ti), aluminum (Al), copper (Cu), gold (Au), and/or a combination thereof, among other examples of electrically conductive metals.

As further shown in FIG. 1, the interconnect layer 114 of the semiconductor die 104 may include a similar combination and/or arrangement of structures and/or layers as the interconnect layer 110 of the semiconductor die 102. For example, the semiconductor die 104 may include a combination of one or more dielectric layers 126 and conductive structures 128 in the dielectric layer(s) 126. Moreover, the interconnect layer 114 may include bonding pads 130 that are electrically coupled with one or more of the conductive structures 128 (e.g., by bonding vias and/or other types of conductive structures). These layers and/or structures may have a reversed vertical arrangement relative to the semiconductor die 102, which enables the semiconductor die 102 and the semiconductor die 104 to be bonded at the bonding interface 106 such that the interconnect layer 110 and the interconnect layer 114 are facing each other.

At the bonding interface 106, the bonding pads 124 of the semiconductor die 102 and the bonding pads 130 of the semiconductor die 104 are directly bonded by metal-to-metal bonds. Moreover, a dielectric layer of the one or more dielectric layers 120 of the semiconductor die 102 and a dielectric layer of the one or more dielectric layers 126 of the semiconductor die 104 are directly bonded by dielectric-to-dielectric bonds.

As further shown in FIG. 1, the semiconductor die 104 may include another interconnect layer 132. The interconnect layer 114 may be located on, and vertically adjacent to, a first side (e.g., a front side) of the device layer 112 of the semiconductor die 104. The interconnect layer 132 may be located on, and vertically adjacent to, a second side (e.g., a back side) of the device layer 112 opposing the first side. The interconnect layer 114 may be configured to route signals and/or power between the semiconductor dies 102 and 104, and/or may be configured to route signals and/or power between integrated circuit devices 118 of the semiconductor die 104. The interconnect layer 132 may be configured to route signals and/or power between the semiconductor die 104 and devices external to the semiconductor die package 100. For example, the interconnect layer 132 may be configured to route signals and/or power between the semiconductor die 104 and an external high bandwidth memory (HBM) die, an external system on chip (SoC) die, an external input/output (I/O) die, and/or another type of device external to the semiconductor die package 100.

The interconnect layer 132 of the semiconductor die 104 includes one or more dielectric layers 134 (e.g., ILD layers, IMD layers, ESLs) and conductive structures 136 (e.g., trenches, metallization layers, vias, interconnect structures) in the dielectric layer(s) 134. The dielectric layer(s) 134 may each include an oxide (e.g., a silicon oxide (SiOₓ) and/or another oxide material), a USG, a BSG, an FSG, an ELK dielectric material, a silicon nitride (SiₓN_{y}), silicon carbide (SiC), silicon oxynitride (SiON), and/or another suitable dielectric material. The conductive structures 136 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The interconnect layer 132 further includes connection structures 138 that enable the semiconductor die package 100 to be attached to a substrate (e.g., an interposer, a printed circuit board (PCB)), another semiconductor die package, and/or to be attached to another structure. The connection structures 138 may include bonding pads and/or another type of connection structures.

As further shown in FIG. 1, the semiconductor die package 100 includes one or more elongated conductive structures 140 that extend between the interconnect layer 114 and 132 through the device layer 112 of the semiconductor die 104. An elongated conductive structure 140 may include a TSV, a metal pillar, a metal column, and/or other another type of vertically elongated conductive structure that physically connects and electrically connects with a conductive structure 128 (e.g., a metal pad) in the interconnect layer 114 at a first end of the elongated conductive structure 140, and that physically connects and electrically connects with a conductive structure 136 (e.g., a metal pad) in the interconnect layer 132 at a second end of the elongated conductive structure 140 opposing the first end. An elongated conductive structure 140 may be referred to as a TSV structure in that the elongated conductive structure 140 extends fully through a semiconductor layer (e.g., a silicon substrate) of the device layer 112 as opposed to extending fully through a dielectric layer or an insulator layer. An elongated conductive structure 140 may further extend through a shallow trench isolation (STI) region 142 that is included in the semiconductor layer of the device layer 112. An elongated conductive structure 140 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material. The STI region 142 may include one or more dielectric materials such as a silicon oxide material (SiOₓ such as SiO₂), a silicon nitride material (SiₓN_{y} such Si₃N₄), and/or another suitable dielectric material.

An elongated conductive structure 140 may include a metal material that is susceptible to diffusion into the semiconductor layer of the device layer 112. Accordingly, one or more liners may be included between the elongated conductive structure 140 and the semiconductor layer of the device layer 112 to provide a diffusion barrier and/or to provide electrical isolation for the elongated conductive structure 140. In some implementations, the one or more liners include a low dielectric constant (low-k) dielectric liner 144 between the semiconductor layer of the device layer 112 and the elongated conductive structure 140. In some implementations, the one or more liners include a high-k dielectric liner 146 between the low-k dielectric liner 144 and the elongated conductive structure 140. In some implementations, other liners are included.

The low-k dielectric liner 144 may include one or more low-k dielectric materials such as a silicon oxide (SiOₓ), an undoped silicate glass (USG), a boron-containing silicate glass (BSG), and/or a fluorine-containing silicate glass (FSG), among other examples.

The high-k dielectric liner 146 includes a high-k oxide dielectric material having a dielectric constant that is greater than 3.9. For example, the high-k dielectric liner 146 may include a high-k oxide dielectric material having a dielectric constant that is at least approximately 7 to 10 or greater. Examples of such high-k oxide dielectric materials include an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. In some implementations, the high-k dielectric liner 146 includes a silicon nitride (SiₓN_{y} such as Si₃N₄) liner. In some implementations, the high-k dielectric liner 146 includes a multiple-layer thin film, where each layer includes a different high-k dielectric material.

A hard mask layer 148 may be included on the back side of the semiconductor layer of the device layer 112. In particular, the hard mask layer 148 is in direct physical contact with the back side surface of the semiconductor layer of the device layer 112, without an intervening high-k dielectric passivation layer between the hard mask layer 148 and the back side surface of the semiconductor layer of the device layer 112. The hard mask layer 148 is included between the device layer 112 and the interconnect layer 132.

The hard mask layer 148 may include a low-k dielectric layer that is patterned and used to etch the semiconductor layer of the device layer 112 to form a recess in which an elongated conductive structure 140 is formed through the semiconductor layer of the device layer 112. Thus, the elongated conductive structure(s) 140 and associated liners 144 and 146 extend through the hard mask layer 148. Examples of low-k dielectric materials that may be used for the hard mask layer 148 include a low-k oxide-containing dielectric material such as a silicon oxide (SiOₓ), an undoped silicate glass (USG), a boron-containing silicate glass (BSG), a fluorine-containing silicate glass (FSG), a high-density plasma (HDP) oxide-containing dielectric material, a high-stress undoped silicate glass (HS-USG) material, and/or a high-stress HDP (HS-HDP) oxide-containing dielectric material, among other examples. In some implementations, the hard mask layer 148 is formed using deposition techniques such as HDP chemical vapor deposition (CVD).

In some implementations, the hard mask layer 148 is formed to a thickness that is included in a range of approximately 3000 angstroms to approximately 5000 angstroms to facilitate forming a high aspect ratio recess for the elongated conductive structure 140. For example, this range for the thickness of the hard mask layer 148 may enable the recess for the elongated conductive structure 140 to be formed to an aspect ratio between the depth of the recesses and the lateral width of the recesses that is at least approximately 8:1 or greater. However, other values and ranges for the thickness of the hard mask layer 148 are within the scope of the present disclosure.

The hard mask layer 148 may be formed directly on the back side surface of the semiconductor layer of the device layer 112 without intervening high-k dielectric passivation layers because of the integrated circuit devices 118 in the device layer 112 being passive integrated circuit devices such as resistors, capacitors, and/or inductors, among other examples. These types of integrated circuit devices are connected to an electrical ground, and the flow of electrical current is contained within conductive electrodes and associated dielectric materials of the integrated circuit devices. Therefore, these types of integrated circuit devices are not as susceptible to current leakage as active integrated circuit devices (such as transistors) that would otherwise include doped regions of the semiconductor layer of the device layer 112. Accordingly, passivation of any damage that might have occurred to the back side surface of the semiconductor layer of the device layer 112 may be omitted because the damage may not significantly contribute to the performance of the integrated circuit devices 118. The hard mask layer 148 can be formed directly on the back side surface of the semiconductor layer of the device layer 112 using lower cost materials (e.g., USG or high density plasma (HDP) silicon dioxide) and lower cost processes compared to the materials and processes used for high-k dielectric passivation layers, which may reduce the cost, complexity, and manufacturing time (e.g., because fewer deposition, etch, and planarization operations are used) for forming the semiconductor die package 100.

As indicated above, FIG. 1 is provided as an example. Other examples may differ from what is described with regard to FIG. 1.

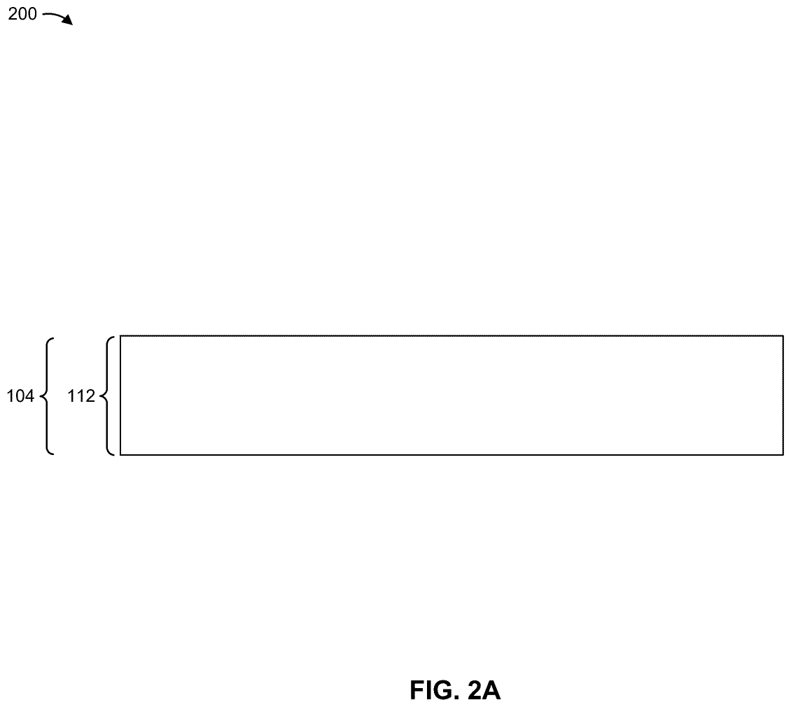

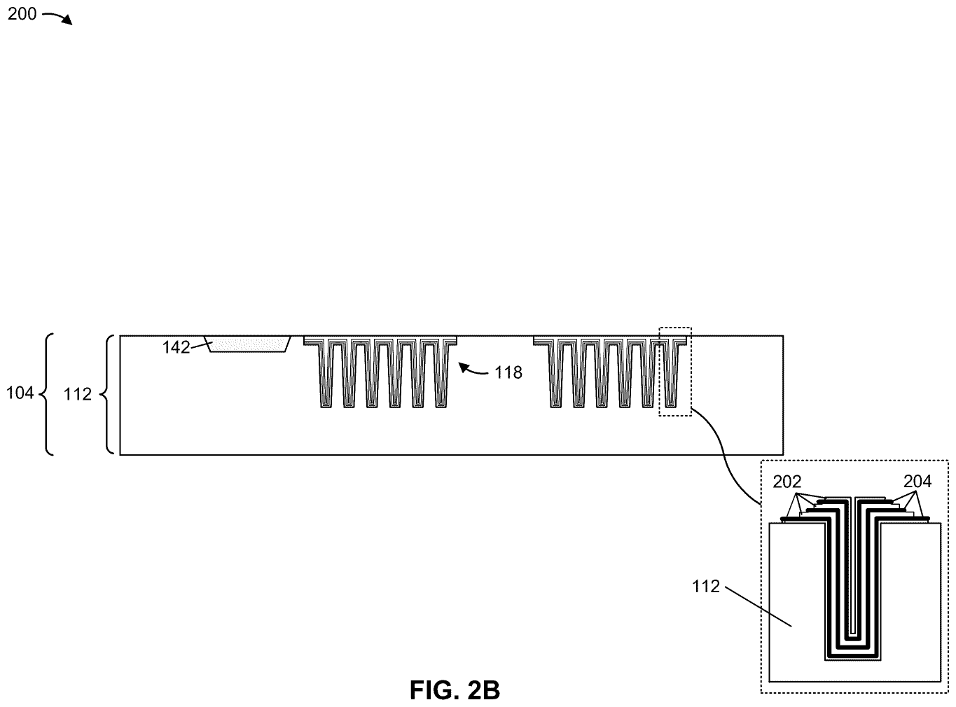

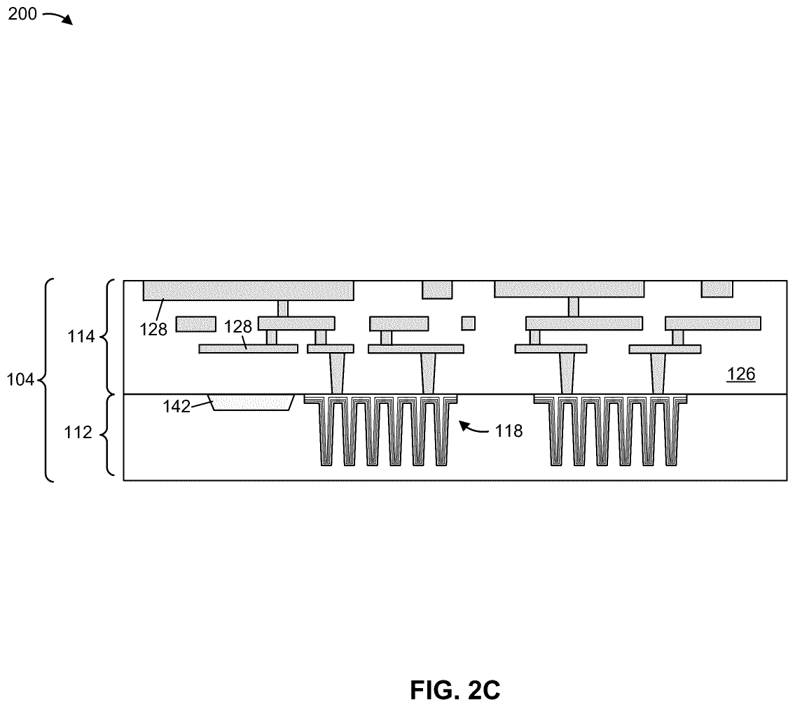

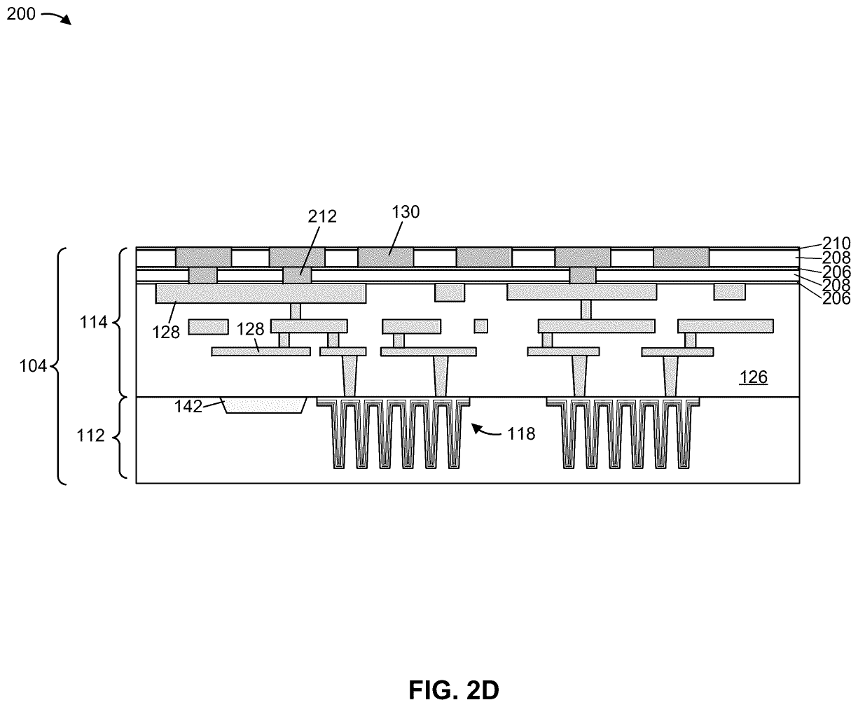

FIGS. 2A-2D are diagrams of an example implementation 200 of forming a semiconductor die described herein. In some implementations, the example implementation 200 includes an example process for forming the semiconductor die 104 or a portion thereof. In some implementations, one or more of the operations described in connection with the example implementation 200 may be performed to form another semiconductor die described herein, such as a semiconductor die 102, among other examples. In some implementations, one or more semiconductor processing tools may be used to perform one or more of the operations described in connection with the example implementation 200, such as a deposition tool, an exposure tool, a developer tool, an etch tool, a planarization tool, a plating tool, and/or another type of semiconductor processing tool.

Turning to FIG. 2A, one or more of the operations in the example implementation 200 may be performed in connection with the semiconductor layer of the device layer 112 of the semiconductor die 104. The semiconductor layer of the device layer 112 may be provided in the form of a semiconductor wafer or another type of semiconductor substrate.

As shown in FIG. 2B, the integrated circuit devices 118 may be formed in and/or on the device layer 112 of the semiconductor die 104. One or more semiconductor processing tools may be used to form one or more portions of the integrated circuit devices 118. For example, a deposition tool may be used to form a photoresist layer on the semiconductor layer of the device layer 112, an exposure tool and a developer tool may be used to form a pattern in the photoresist layer, and an etch tool may be used to etch the semiconductor layer of the device layer 112 to form recesses (e.g., deep trenches) in the semiconductor layer of the device layer 112. As another example, a deposition tool may be used to perform various deposition operations to deposit layers of the integrated circuit devices 118, including electrode layers 202 and insulating layers 204 of DTCs in the recesses, using a CVD technique, an atomic layer deposition (ALD) technique, a physical vapor deposition (PVD) technique, an oxidation technique, and/or another suitable deposition technique.

As further shown in FIG. 2B, an STI region 142 may be formed in the device layer 112. The STI region 142 may be formed in a recess in the device layer 112. In some implementations, a pattern in a photoresist layer is used to etch the device layer 112 to form the recess in the device layer 112. In these implementations, a deposition tool may be used to form the photoresist layer on the device layer 112. An exposure tool may be used to expose the photoresist layer to a radiation source to pattern the photoresist layer. A developer tool may be used to develop and remove portions of the photoresist layer to expose the pattern. An etch tool may be used to etch the device layer 112 based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the device layer 112 based on a pattern.

A deposition tool may be used to deposit the dielectric material of the STI region 142 in the recess using a CVD technique, an ALD technique, a PVD technique, an oxidation technique, and/or another suitable deposition technique. The dielectric material of the STI region 142 may be deposited in one or more deposition operations. In some implementations, a planarization tool may be used to perform a planarization operation (e.g., a chemical mechanical planarization (CMP) operation) to planarize the STI region 142 after the dielectric material of the STI region 142 is deposited.

As shown in FIG. 2C, the interconnect layer 114 of the second semiconductor die 104 may be formed over and/or on a front side of the semiconductor layer of the device layer 112. One or more semiconductor processing tools may be used to form the interconnect layer 114 by forming one or more dielectric layers 126 and forming a plurality of conductive structures 128 in the dielectric layer(s) 126. For example, a deposition tool may be used to deposit a first layer of the dielectric layer(s) 126 (e.g., using a CVD technique, an ALD technique, a PVD technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 128 in the recesses (e.g., using a CVD technique, an ALD technique, a PVD technique, an electroplating technique, and/or another type of deposition technique). At least a portion of the first layer of conductive structures 128 may be electrically connected and/or physically connected with the integrated circuit devices 118 in the device layer 112 (e.g., directly connected or connected through contacts). Similar processing operations may be performed to form additional layers of the interconnect layer 114 until a sufficient or desired arrangement of conductive structures 128 is achieved.

As shown in FIG. 2D, additional dielectric layers of the interconnect layer 114 may be formed, such as an alternating arrangement of nitride dielectric layers 206 and oxide dielectric layers 208. A bonding dielectric layer 210 may be formed on the alternating arrangement of nitride dielectric layers and oxide dielectric layers. The nitride dielectric layers 206 may include a silicon nitride material (SiₓN_{y} such as Si₃N₄) and/or another suitable nitride-containing dielectric material. The oxide dielectric layers 208 may include a silicon oxide material (SiOₓ such as SiO₂) and/or another suitable oxide-containing dielectric material. The bonding dielectric layer 210 may include a silicon oxynitride material (SiON) and/or another suitable bonding dielectric material. A deposition tool may be used to deposit the nitride dielectric layers 206, the oxide dielectric layers 208, and the bonding dielectric layer 210, each using a CVD technique, an ALD technique, a PVD technique, an oxidation technique, and/or another suitable deposition technique. In some implementations, a planarization tool may be used to perform a planarization operation (e.g., a CMP operation) to planarize the nitride dielectric layers 206, the oxide dielectric layers 208, and/or the bonding dielectric layer 210.

In some implementations, a photoresist layer may be formed over the bonding dielectric layer 210. The photoresist layer may be formed using a deposition tool by spin-coating and/or another suitable photoresist coating technique. Via portions of recesses may be formed through the nitride dielectric layers 206, the oxide dielectric layers 208, and the bonding dielectric layer 210. One or more of the conductive structures 128 in the interconnect layer 114 may be exposed through the recesses. Trench portions of at least a subset of the recesses may also be through the nitride dielectric layers 206, the oxide dielectric layers 208, and the bonding dielectric layer 210. Thus, at least a subset of the recesses may be dual damascene recesses that have a via portion and a trench portion. Another subset of the recesses may include single damascene recesses having only a trench portion.

Bonding vias 212 may be formed in the via portions of the recesses, and bonding pads 130 may be formed in the trench portions of the recesses and in the single damascene recesses. A deposition tool may be used to deposit the bonding vias 212 and the bonding pads 130 using a CVD technique, a PVD technique, an ALD technique, an electroplating technique, and/or another suitable deposition technique. The bonding vias 212 and the bonding pads 130 may be deposited in one or more deposition operations. In some implementations, a seed layer is first deposited, and the bonding vias 212 and the bonding pads 130 are deposited on the seed layer.

In some implementations, a planarization tool is used to perform a planarization operation (e.g., a CMP operation) to planarize the bonding pads 130 after the bonding pads 130 are deposited.

As indicated above, FIGS. 2A-2D are provided as an example. Other examples may differ from what is described with regard to FIGS. 2A-2D.

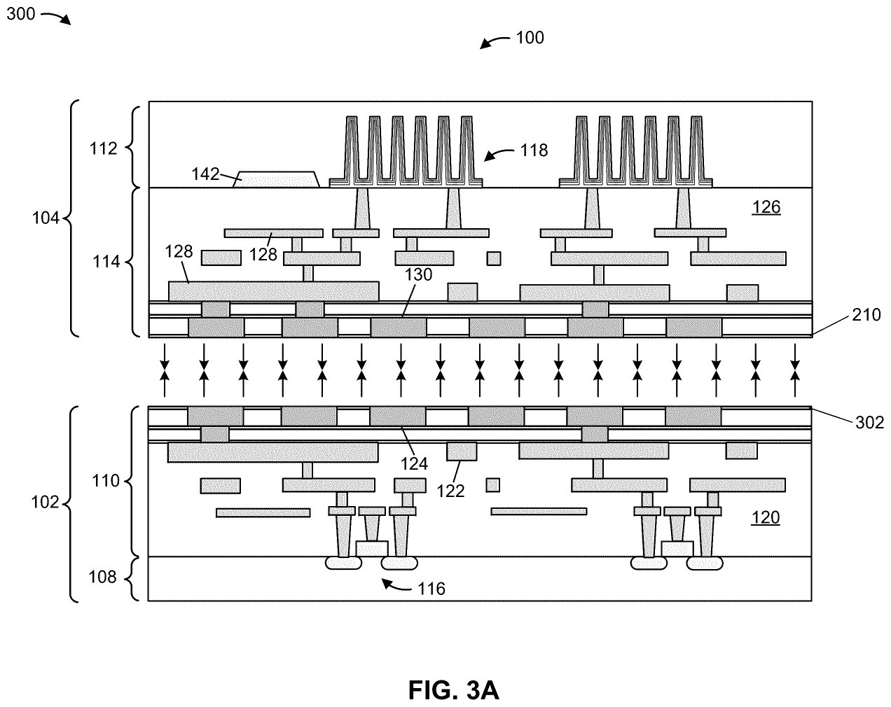

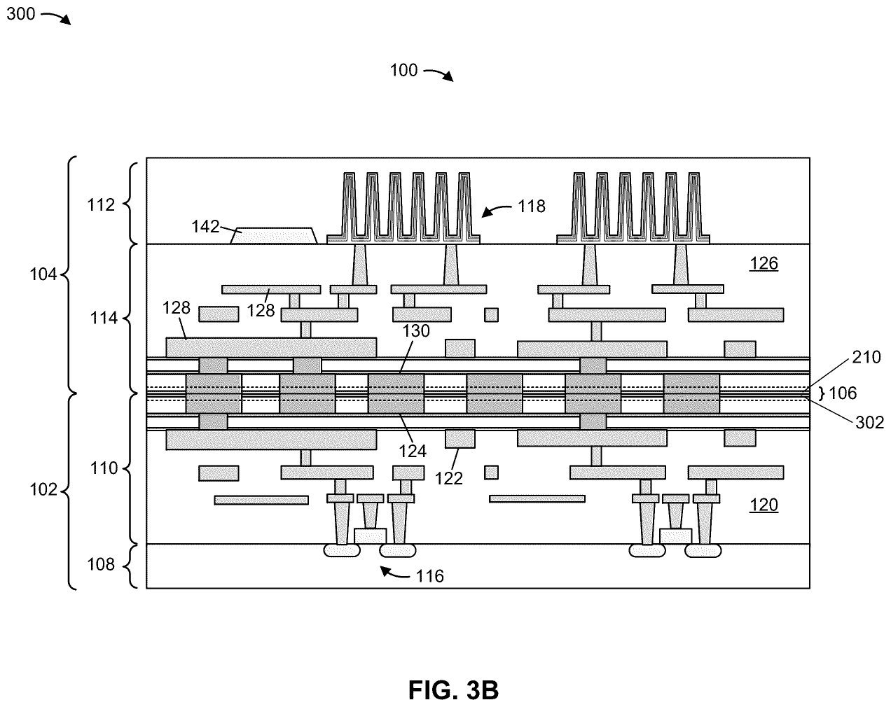

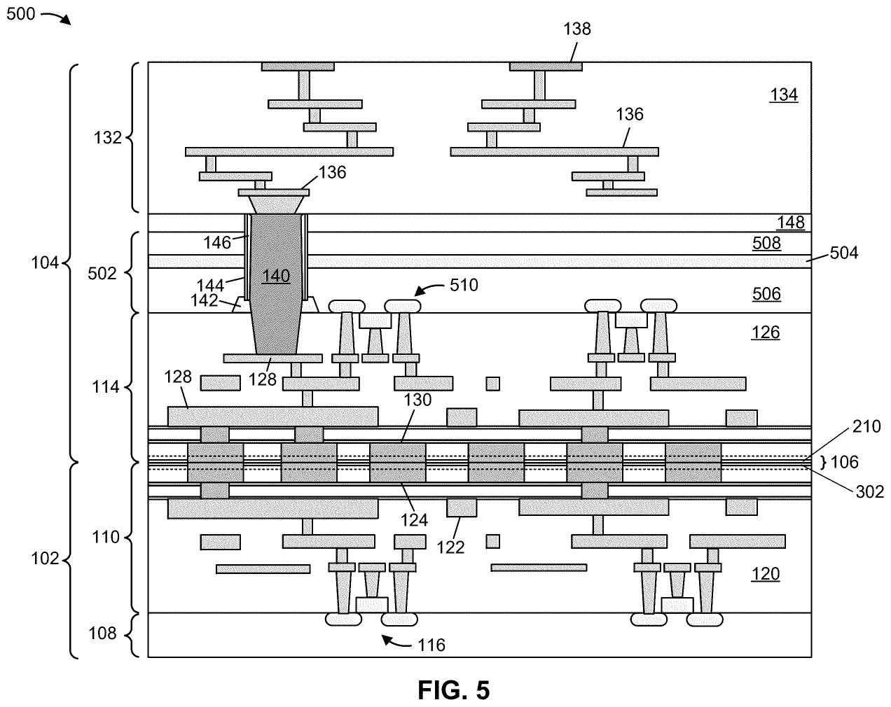

FIGS. 3A and 3B are diagrams of an example implementation 300 of forming a semiconductor die package described herein. For example, the example implementation 300 may include an example of forming a semiconductor die package 100. In some implementations, one or more of the operations described in connection with the example implementation 300 may be performed to form another semiconductor die package described herein, such as a semiconductor die package 500 illustrated in FIG. 5, among other examples. In some implementations, one or more semiconductor processing tools may be used to perform one or more of the operations described in connection with the example implementation 300, such as a bonding tool, deposition tool, an etch tool, a planarization tool, and/or another type of semiconductor processing tool.

As shown in FIGS. 3A and 3B, a bonding operation is performed to bond the semiconductor die 102 and the semiconductor die 104 at the bonding interface 106 such that the semiconductor die 102 and the semiconductor die 104 are vertically arranged or stacked in the semiconductor die package 100. The semiconductor die 102 and the semiconductor die 104 may be vertically arranged or stacked in a wafer on wafer (WoW) configuration, a die on wafer configuration, a die on die configuration, and/or another direct bonding configuration. A bonding tool may be used to perform the bonding operation to bond the semiconductor die 102 and the semiconductor die 104 at the bonding interface 106. The bonding operation may include forming a direct bond between the semiconductor die 102 and the semiconductor die 104 through a direct physical connection (e.g., metal-to-metal bonds) of the bonding pads 124 of the semiconductor die 102 with the bonding pads 130 of the semiconductor die 104, and through a direct physical connection (e.g., dielectric-to-dielectric bonds) of a bonding dielectric layer 302 of the semiconductor die 102 with the bonding dielectric layer 210 of the semiconductor die 104. In this way, the interconnect layer 110 of the semiconductor die 102 is facing the interconnect layer 114 of the semiconductor die 104.

As indicated above, FIGS. 3A and 3B are provided as an example. Other examples may differ from what is described with regard to FIGS. 3A and 3B.

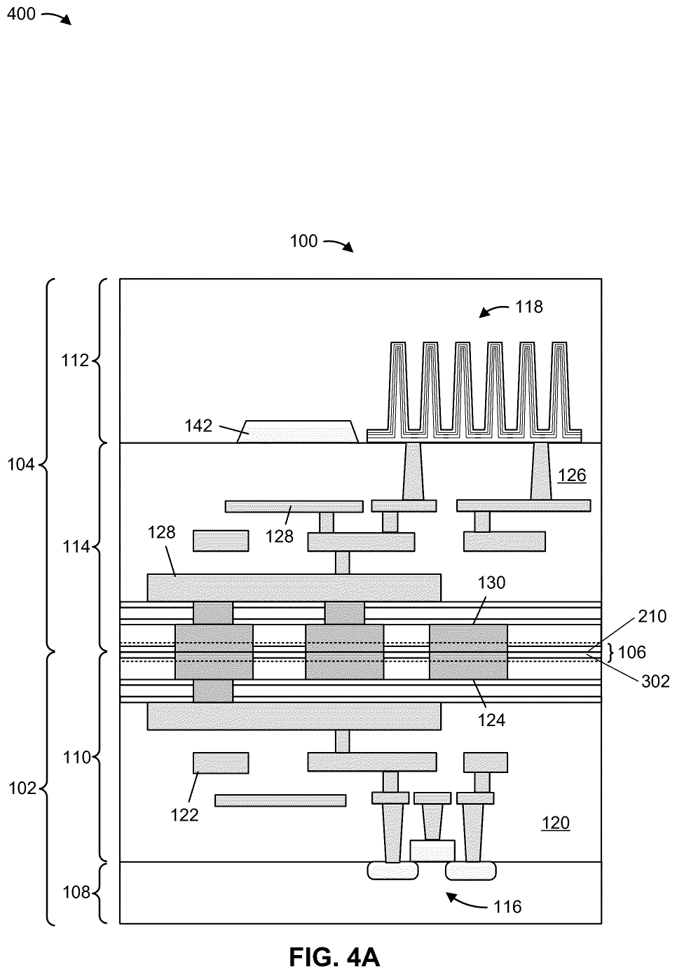

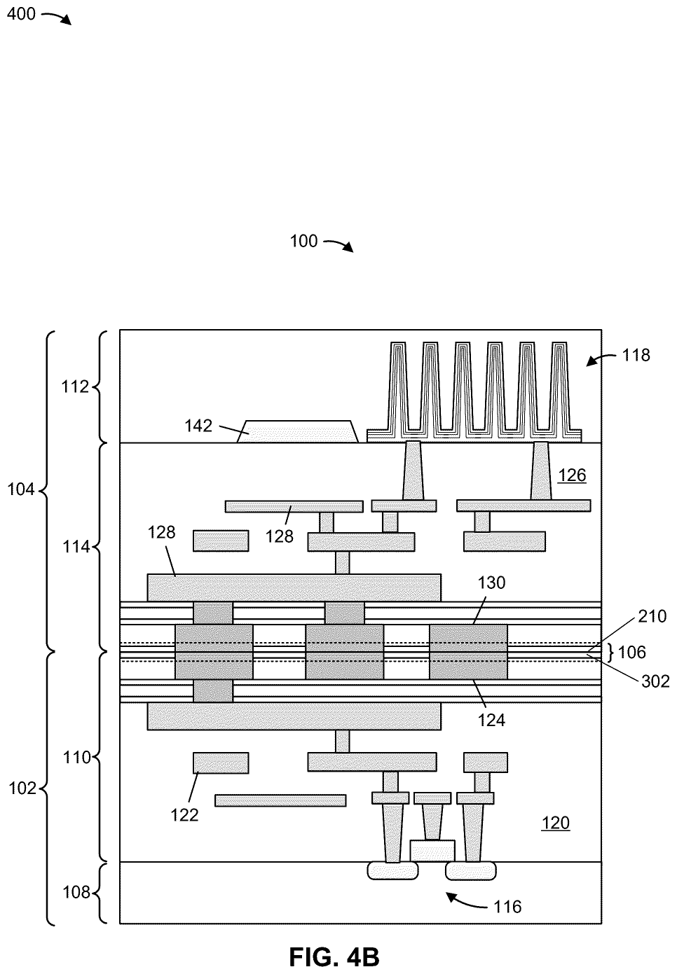

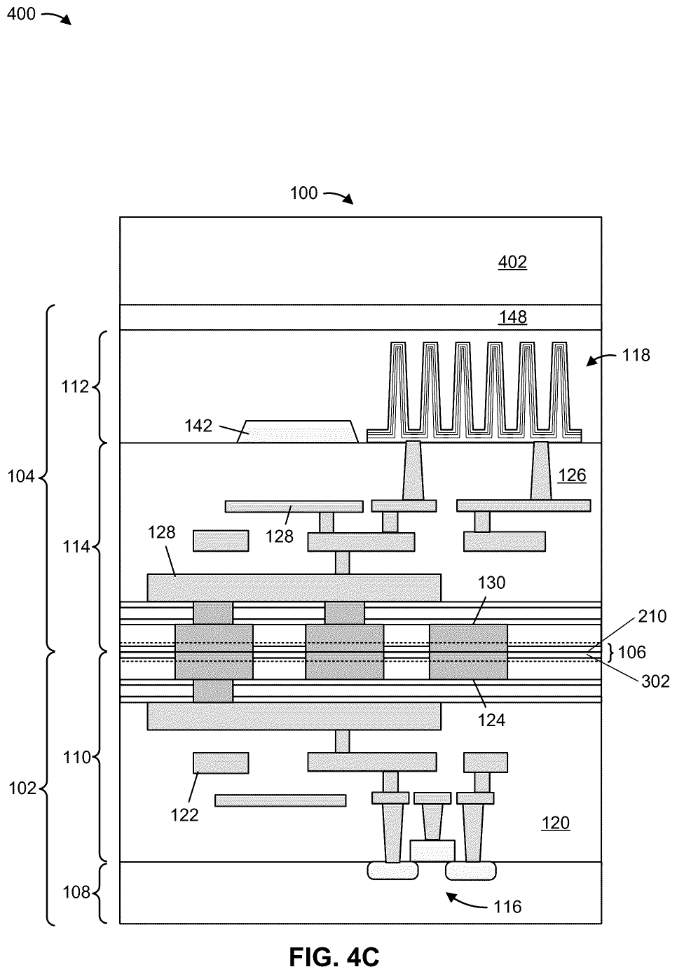

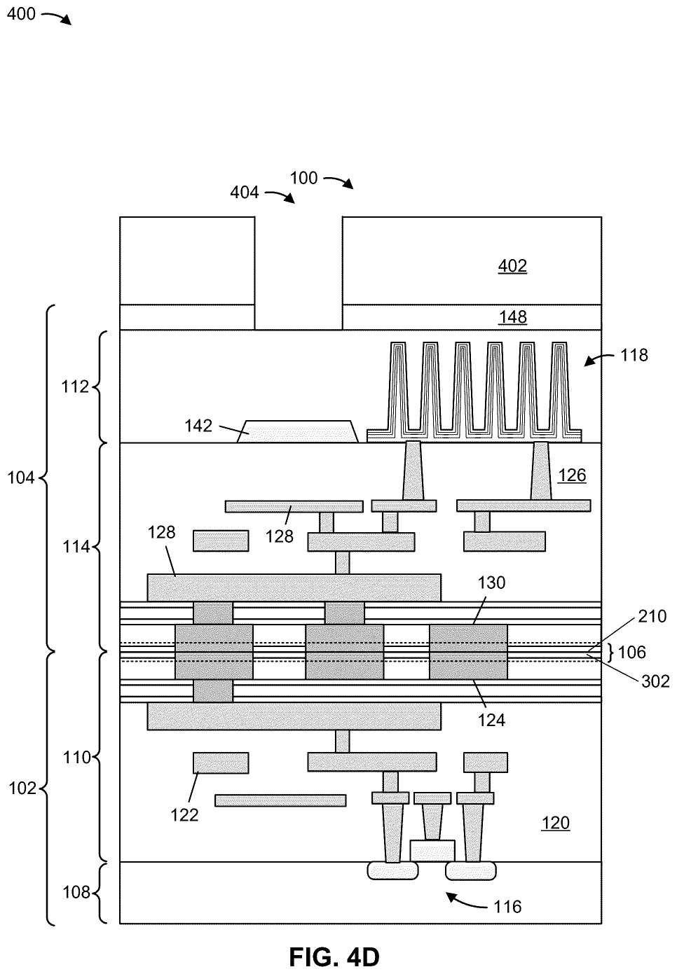

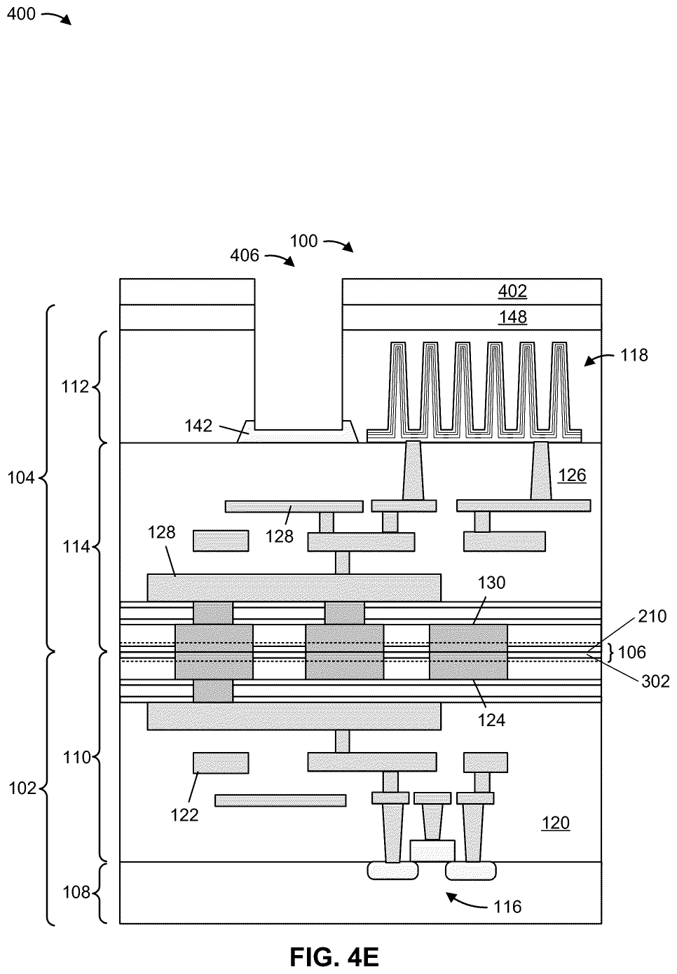

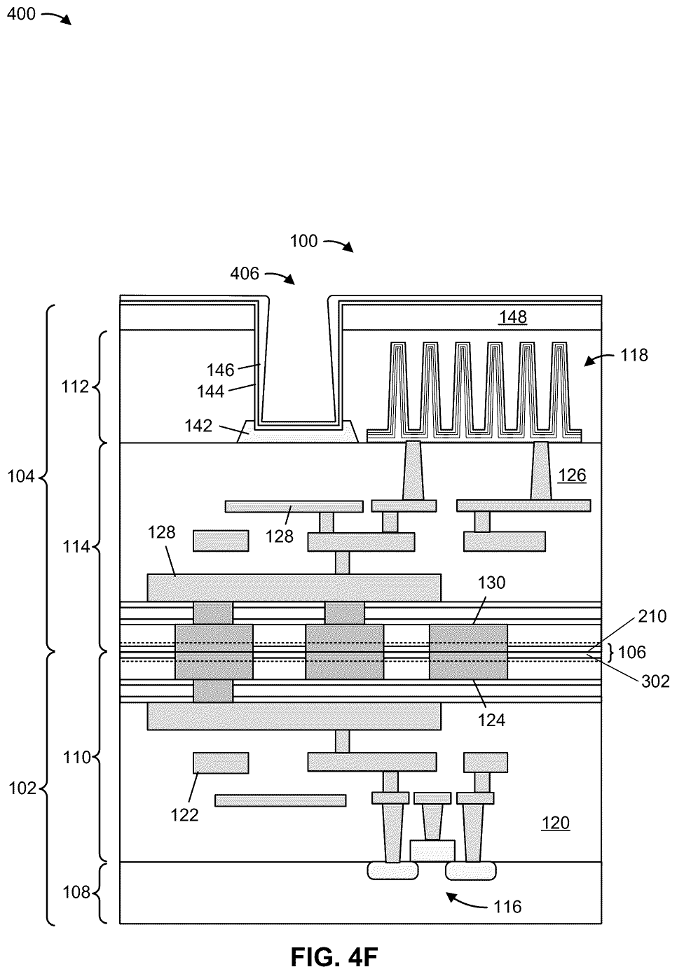

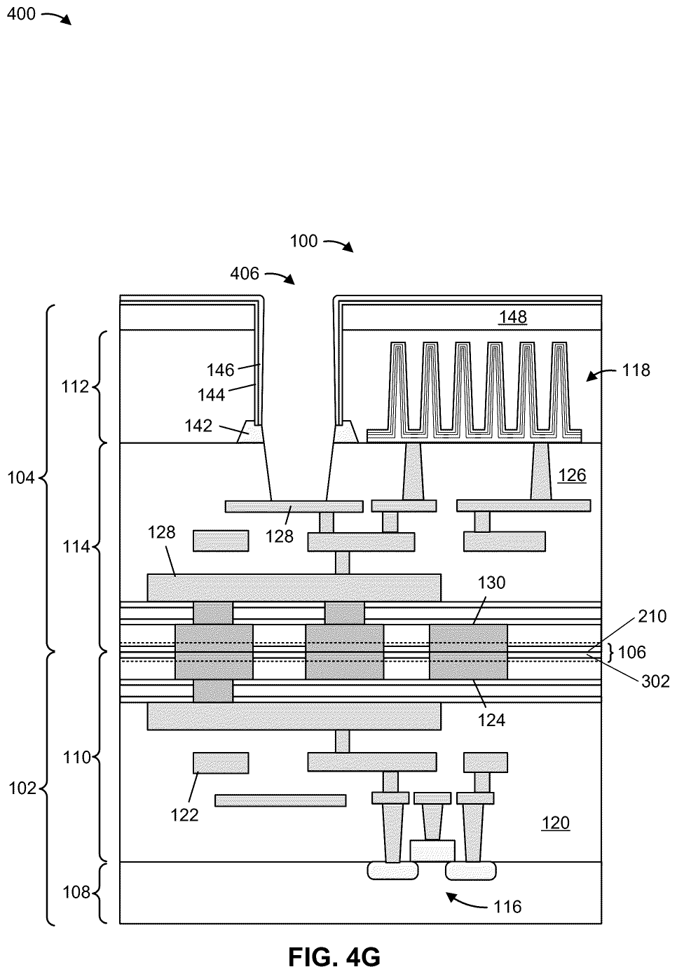

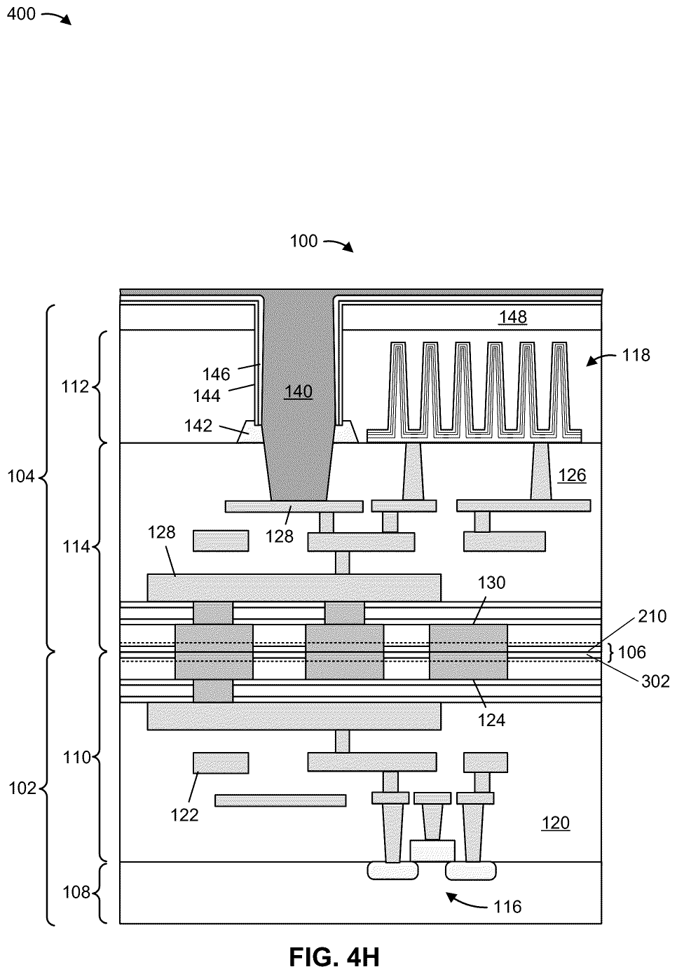

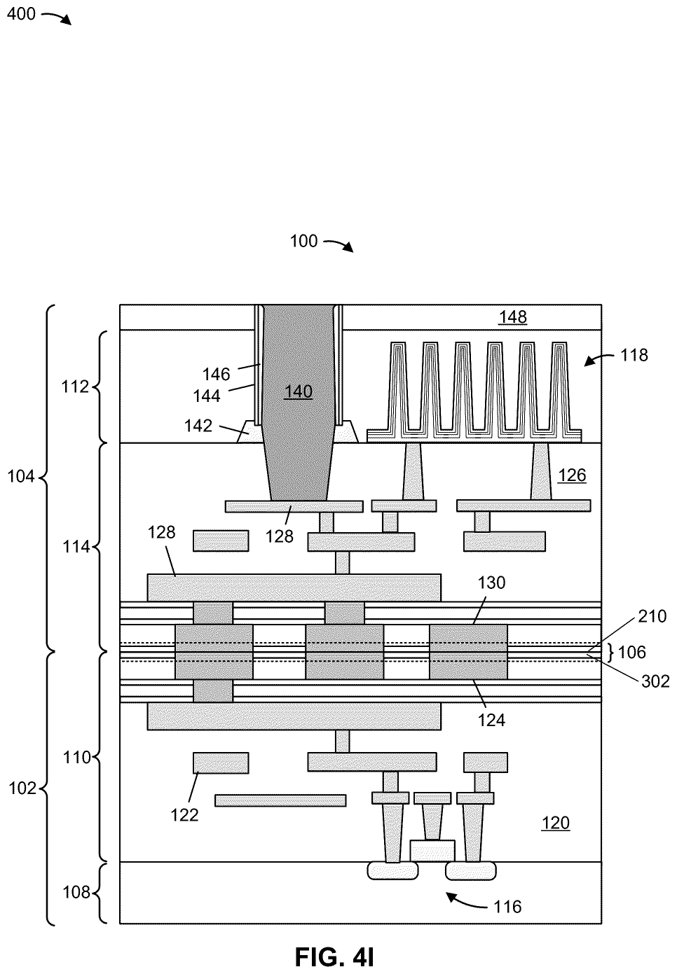

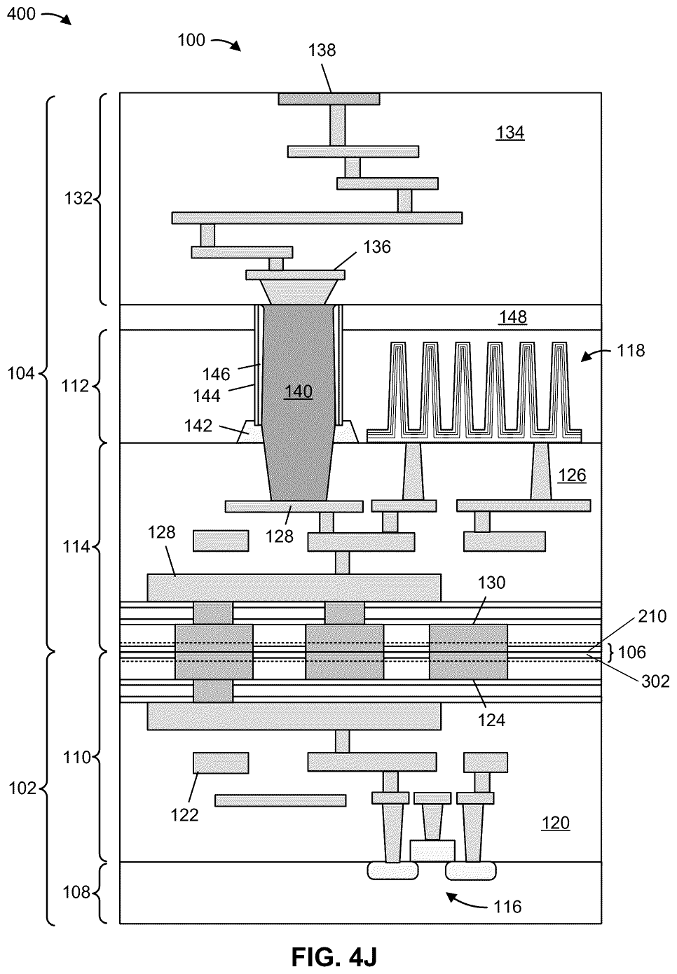

FIGS. 4A-4J are diagrams of an example implementation 400 of forming an elongated conductive structure 140 (e.g., a TSV) described herein. In some implementations, the example implementation 400 includes an example process for forming the elongated conductive structure 140 through the device layer 112 of the semiconductor die 104 included in the semiconductor die package 100. In some implementations, one or more semiconductor processing tools may be used to perform one or more of the operations described in connection with the example implementation 400, such as a deposition tool, an exposure tool, a developer tool, an etch tool, a planarization tool, a plating tool, and/or another type of semiconductor processing tool.

Turning to FIG. 4A, the semiconductor processing operations described in connection with FIGS. 4A-4J may be performed in connection with the back side of the semiconductor layer of the device layer 112 of the semiconductor die 104. The semiconductor processing operations described in connection with FIGS. 4A-4J may be performed after front side processing (e.g., after forming the integrated circuit devices 118 and after forming the interconnect layer 114) of the semiconductor die 104, as described in connection with FIGS. 2A-2D. Moreover, the semiconductor processing operations described in connection with FIGS. 4A-4J may be performed after bonding the semiconductor die 102 and the semiconductor die 104 to form the semiconductor die package 100 as described in connection with FIGS. 3A and 3B.

As shown in FIG. 4B, a grinding operation (e.g., a wafer grinding operation) may be performed on the back side of the semiconductor layer of the device layer 112. A wafer grinding tool may be used to perform the grinding operation. The grinding operation may be performed to reduce the thickness of the semiconductor layer of the device layer 112 in preparation for forming one or more conductive structures 140 through the semiconductor layer of the device layer 112. In some implementations, the thickness of the semiconductor layer of the device layer 112 after the grinding operation may be included in a range of approximately 2.7 microns to approximately 11 microns. However, other values and ranges are within the scope of the present disclosure.

As shown in FIG. 4C, the hard mask layer 148 is formed directly on the back side of the semiconductor layer of the device layer 112 after the grinding operation. Thus, the hard mask layer 148 is in direct physical contact with the semiconductor layer of the device layer 112 without an intervening passivation layer (e.g., without an intervening high-k passivation layer) between the hard mask layer 148 and the semiconductor layer of the device layer 112.

A deposition tool may be used to deposit the hard mask layer 148 using a CVD technique (e.g., an HDP CVD technique, a plasma enhanced CVD (PECVD) technique, an ALD technique, a PVD technique, an oxidation technique, and/or another suitable deposition technique). In some implementations, a planarization tool may be used to perform a planarization operation (e.g., a CMP operation) to planarize the hard mask layer 148 after the hard mask layer 148 is deposited.

In some implementations, the hard mask layer 148 may be formed to a thickness that is included in a range of approximately 3000 angstroms to approximately 5000 angstroms. If the hard mask layer 148 is formed to a thickness of less than approximately 3000 angstroms, the hard mask layer 148 may not be sufficiently thick to enable the hard mask layer 148 to be used to form high aspect ratio recesses for the elongated conductive structure(s) 140 that are to be formed through the device layer 112. If the hard mask layer 148 is formed to a thickness that is greater than approximately 5000 angstroms, the thickness of the hard mask layer 148 may result in under-etching of the recesses for the elongated conductive structure(s) 140 and/or may result in insufficient gap-filling performance for the elongated conductive structure(s) 140. This may prevent electrical connections from being formed between the elongated conductive structure(s) 140 and the conductive structures 128 and 136. If the hard mask layer 148 is formed to a thickness that is included in the range of approximately 3000 angstroms to approximately 5000 angstroms, the recesses for the elongated conductive structure(s) 140 may be formed to a sufficiently high aspect ratio while increasing the likelihood of full etching and gap-filling of the recesses for forming electrical connections between the elongated conductive structure(s) 140 and the conductive structures 128 and 136. However, other values and ranges other than approximately 3000 angstroms to approximately 5000 angstroms for the thickness of the hard mask layer 148 are within the scope of the present disclosure.

As further shown in FIG. 4C, a photoresist layer 402 may be formed over and/or on the hard mask layer 148. In some implementations, a deposition tool may be used to deposit the photoresist layer 402 using a spin-coating technique and/or another suitable deposition technique. In some implementations, the photoresist layer 402 is formed to a thickness that is included in a range of approximately 30 microns to approximately 40 microns. However, other values and ranges for the thickness of the photoresist layer 402 are within the scope of the present disclosure.

As shown in FIG. 4D, the photoresist layer 402 may be used to form a pattern 404 in the hard mask layer 148. An exposure tool may be used to expose the photoresist layer 402 to a radiation source to form the pattern 404 in the photoresist layer 402. A developer tool may be used to develop and remove portions of the photoresist layer 402 to expose the pattern 404. An etch tool may be used to etch the hard mask layer 148 based on the pattern 404 to transfer the pattern 404 to the hard mask layer 148. In some implementations, the etch operation includes a dry etch operation (e.g., a plasma-based etch operation, a gas-based etch operation), a wet chemical etch operation, and/or another type of etch operation.

As shown in FIG. 4E, a first etch operation is performed to form a recess 406 in the semiconductor layer of the device layer 112 based on the pattern 404 in the photoresist layer 402 and in the hard mask layer 148. The recess 406 may be formed into the semiconductor layer of the device layer 112 from the back side of the semiconductor layer of the device layer 112. In some implementations, the first etch operation stops on the STI region 142 in the semiconductor layer of the device layer 112. In some implementations, some over-etching occurs, and the recess 406 partially extends into the STI region 142.

An etch tool may be used to perform the first etch operation to etch the semiconductor layer of the device layer 112 based on the pattern 404 to form the recess 406. In some implementations, the first etch operation includes a dry etch operation (e.g., a plasma-based etch operation, a gas-based etch operation), a wet chemical etch operation, and/or another type of etch operation. The combination of the photoresist layer 402 and the hard mask layer 148 protects the back side of the semiconductor layer of the device layer 112 from being etched during the first etch operation. In some implementations, the photoresist layer 402 is partially consumed in the first etch operation, resulting in a reduction in thickness of the photoresist layer 402. In some implementations, a photoresist removal tool may be used to remove the remaining portions of the photoresist layer (e.g., using a chemical stripper, plasma ashing, and/or another technique) after the etch operation.

As shown in FIG. 4F, one or more liners may be formed on the sidewalls and the bottom surface of the recess 406 after the first etch operation. The one or more liners may include a low-k dielectric liner 144 and/or a high-k dielectric liner 146, among other examples. In some implementations, the low-k dielectric liner 144 and/or the high-k dielectric liner 146 are also deposited over the back side of the semiconductor layer of the device layer 112 to protect the semiconductor layer from being damaged in a subsequent etch operation.

A deposition tool may be used to deposit the low-k dielectric liner 144 using an ALD technique, a CVD technique, and/or another suitable conformal deposition technique. A deposition tool may be used to deposit the high-k dielectric liner 146 using an ALD technique (e.g., plasma-enhanced ALD (PEALD), plasma-enhanced silicon nitride (PESN) ALD), a CVD technique, and/or another suitable conformal deposition technique). The deposition process (e.g., PESN) that is used to deposit the high-k dielectric liner 146 may result in the high-k dielectric liner 146 being thicker at the top of the recess 406 than at the bottom of the recess. This may result in an overhang of the material of the high-k dielectric liner 146 at the top of the recess 406.

In some implementations, the low-k dielectric liner 144 is formed to a thickness that is included in a range of approximately 1000 angstroms to approximately 2000 angstroms. However, other values and ranges for the thickness of the low-k dielectric liner 144 are within the scope of the present disclosure. In some implementations, the high-k dielectric liner 146 is formed to a thickness that is included in a range of approximately 1500 angstroms to approximately 2500 angstroms. However, other values and ranges for the thickness of the high-k dielectric liner 146 are within the scope of the present disclosure. In some implementations, the high-k dielectric liner 146 may be formed to a greater thickness than the low-k dielectric liner 144.

As shown in FIG. 4G, a second etch operation is performed to etch through the STI region 142 such that the recess 406 extends to the underlying conductive structure 128 in the interconnect layer 114. Thus, the depth of the recess 406 is increased from the first depth to a second depth during the second etch operation, and the conductive structure 128 is exposed through the recess 406 after the second etch operation.

In some implementations, the second etch operation includes a dry etch operation (e.g., a plasma-based etch operation, a gas-based etch operation), a wet chemical etch operation, and/or another type of etch operation. In some implementations, the second etch operation is performed as a self-aligned etch operation in that the recess 406 is etched without an additional photoresist layer. The hard mask layer 148, the low-k dielectric liner 144, and the high-k dielectric liner 146 may function as an etch stop layer on the back side surface of the semiconductor layer of the device layer 112, and may protect the back side surface of the semiconductor layer from being etched during the second etch operation.

The low-k dielectric liner 144 on the sidewalls of the recess 406 and the high-k dielectric liner 146 on the sidewalls of the recess 406 protect the sidewalls of the recess 406 from being etched and laterally expanded, thereby preserving the high aspect ratio of the recess 406. The overhang of the material of the high-k dielectric liner 146 may result in the high-k dielectric liner 146 on the bottom surface of the recess 406 being etched through, while some of the high-k dielectric liner 146 at the top of the recess 406 remains on the sidewalls of the recess 406 after the etch operation.

As shown in FIG. 4H, an elongated conductive structure 140 may be formed in the recess 406 such that the elongated conductive structure 140 lands on the underlying conductive structure 128. A deposition tool may be used to deposit the elongated conductive structure 140 using a CVD technique, a PVD technique, an ALD technique, an electroplating technique, and/or another suitable deposition technique. The elongated conductive structure 140 may be deposited in one or more deposition operations. In some implementations, a seed layer is first deposited, and the elongated conductive structure 140 is deposited on the seed layer. The seed layer may include a copper (Cu) seed layer and/or another suitable seed layer. In some implementations, additional liners (e.g., a tantalum nitride (TaN) liner) are deposited in the recess 406 prior to the seed layer.

As shown in FIG. 4I, a planarization tool is used to perform a planarization operation (e.g., a CMP operation) to planarize the elongated conductive structure 140 after the elongated conductive structure 140 is deposited. Excess material of the elongated conductive structure 140 may be removed from on otp of the hard mask layer 148 in the planarization operation. In some implementations, portions of the low-k dielectric liner 144 and the portions of the high-k dielectric liner 146 remaining on the hard mask layer 148 may be removed in the planarization operation.

As shown in FIG. 4J, the interconnect layer 132 is formed above the back side of the semiconductor layer of the device layer 112 after formation of the elongated conductive structure 140. The interconnect layer 132 may be formed on the hard mask layer 148.

Forming the interconnect layer 132 may include similar operations as described in connection with FIG. 2C for the interconnect layer 114. For example, one or more dielectric layers 134 of the interconnect layer 132 may be deposited (e.g., using a CVD technique, a PVD technique, an ALD technique, an oxidation technique, and/or another suitable deposition technique), and the conductive structures 136 and the connection structures 138 may be formed in the dielectric layer(s) 134 (e.g., using a CVD technique, a PVD technique, an ALD technique, an electroplating technique, and/or another suitable deposition technique). Alternatively, metal layers may be deposited, patterned, and etched to form the conductive structures 136 and the connection structures 138, and the dielectric layer(s) 134 may be formed around the conductive structures 136 and the connection structures 138.

As indicated above, FIGS. 4A-4J are provided as an example. Other examples may differ from what is described with regard to FIGS. 4A-4J.

FIG. 5 is a diagram of an example semiconductor die package 500 described herein. FIG. 5 illustrates a cross-section view of the semiconductor die package 500. As shown in FIG. 5, the semiconductor die package 500 includes a semiconductor die 102 and a semiconductor die 104 bonded at a bonding interface 106, similar to the semiconductor die package 100 of FIG. 1. However, the semiconductor die 104 includes a device layer 502 that includes a silicon on insulator (SOI) substrate.

The SOI substrate of the device layer 502 includes a buried oxide (BOX) layer 504 sandwiched between a first semiconductor layer 506 (e.g., a front side semiconductor layer) and a second semiconductor layer 508 (e.g., a back side semiconductor layer). The buried oxide layer 504, the first semiconductor layer 506, and the second semiconductor layer 508 may be stacked or vertically arranged in the semiconductor die 104, with the buried oxide layer 504 physically and electrically separating the first semiconductor layer 506 and the second semiconductor layer 508. The first semiconductor layer 506 faces the interconnect layer 114 on the front side of the SOI substrate, and the second semiconductor layer 508 faces the interconnect layer 132 on the back side of the SOI substrate.

The buried oxide layer 504 may include a silicon oxide (SiOₓ such as SiO₂) layer and/or another suitable electrically insulating dielectric material. The first semiconductor layer 506 and the second semiconductor layer 508 may each include one or more semiconductor materials, such as silicon (Si), silicon that is doped with one or more types of dopants (e.g., p-type dopants, n-type dopants), and/or another suitable semiconductor material.

Integrated circuit devices 510 of the semiconductor die 104 may be included in the first semiconductor layer 506 of the SOI substrate of the device layer 502. The integrated circuit devices 116 may include active integrated circuit components such as transistors (e.g., planar transistors, finFETs, gate all around (GAA) transistors), optical modulators, transceivers, transmitters, receivers, photodetectors, and/or semiconductor-based heaters, among other examples. Moreover, the integrated circuit devices 116 may include passive integrated circuit components such as capacitors, resistors, inductors, and/or waveguides, among other examples.

One or more elongated conductive structures 140 may extend through the SOI substrate of the device layer 502, and may be electrically coupled and/or physically coupled with a conductive structure in the interconnect layer 114 and another conductive structure 136 in the interconnect layer 132. The elongated conductive structure(s) 140 and associated liners 144, 146 may extend through the buried oxide layer 504, the first semiconductor layer 506, and the second semiconductor layer 508 of the SOI substrate. The elongated conductive structure(s) 140 may also extend through associated STI regions 142 that may be located in the first semiconductor layer 506.

As further shown in FIG. 5, the hard mask layer 148 may be located directly on the back side surface of the SOI substrate, which corresponds to the second semiconductor layer 508. Thus, the hard mask layer 148 is in direct physical contact with the second semiconductor layer 508 without intervening high-k passivation layers between the hard mask layer 148 and the second semiconductor layer 508. High-k passivation layers may be omitted even though the integrated circuit devices 510 may include active integrated circuit devices such as transistors because the buried oxide layer 504 electrically isolates the integrated circuit devices 510 in the first semiconductor layer 506 from any damage that may have occurred to the second semiconductor layer 508 due to wafer grinding of the second semiconductor layer 508. Accordingly, passivation of any damage that might have occurred to the back side surface of the SOI substrate of the device layer 502 may be omitted because the damage may not significantly contribute to the performance of the integrated circuit devices 510. The hard mask layer 148 can be formed directly on the back side surface of the SOI substrate of the device layer 502 using lower cost materials (e.g., USG or HDP silicon dioxide) and lower cost processes compared to the materials and processes used for high-k dielectric passivation layers, which may reduce the cost, complexity, and manufacturing time (e.g., because fewer deposition, etch, and planarization operations are used) for forming the semiconductor die package 500.

As indicated above, FIG. 5 is provided as an example. Other examples may differ from what is described with regard to FIG. 5.

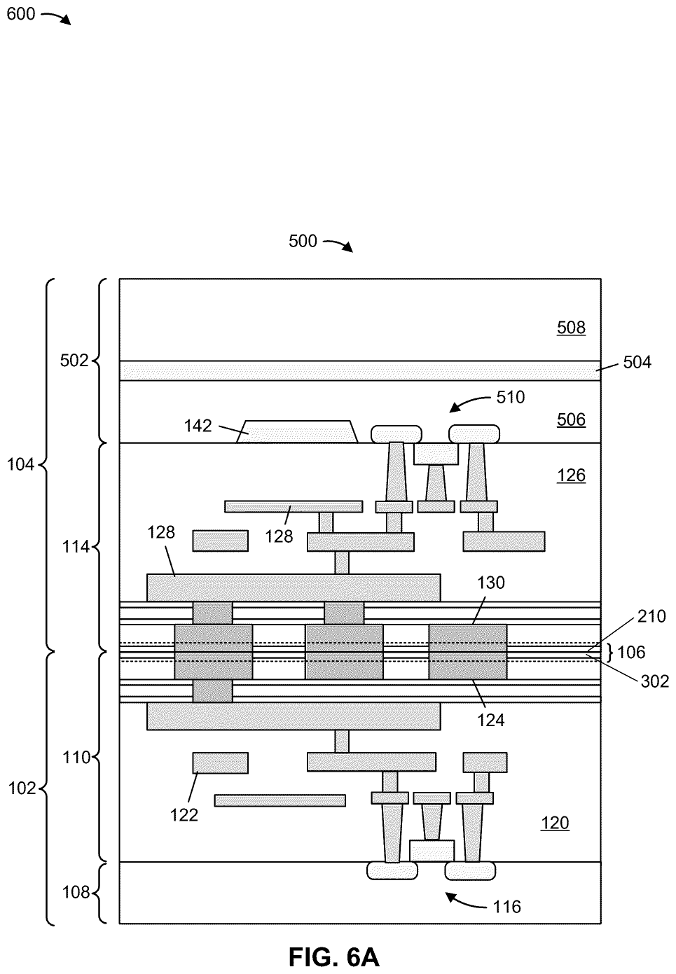

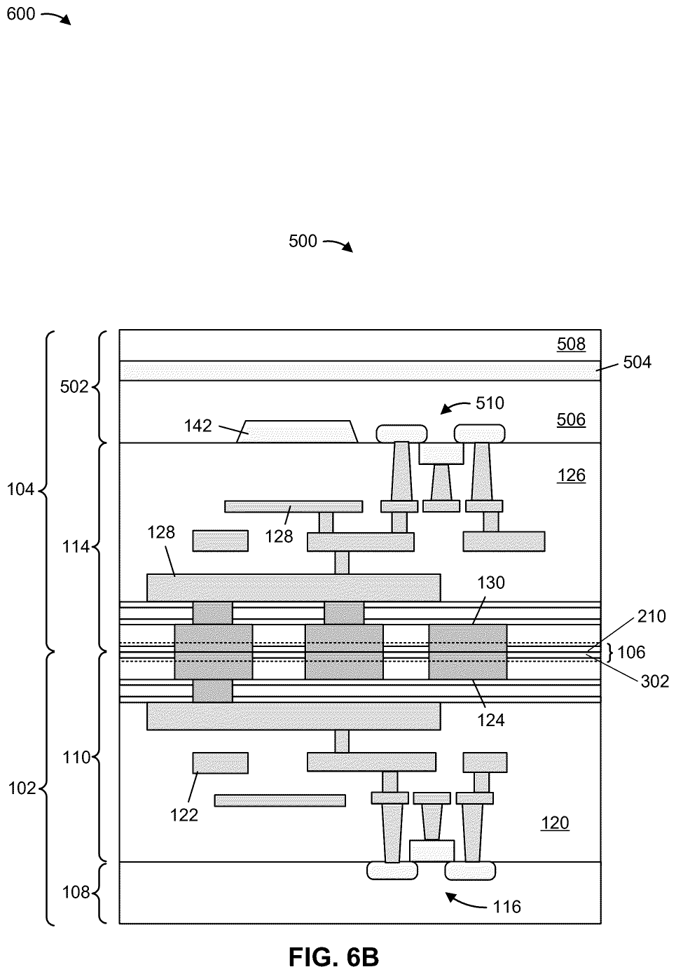

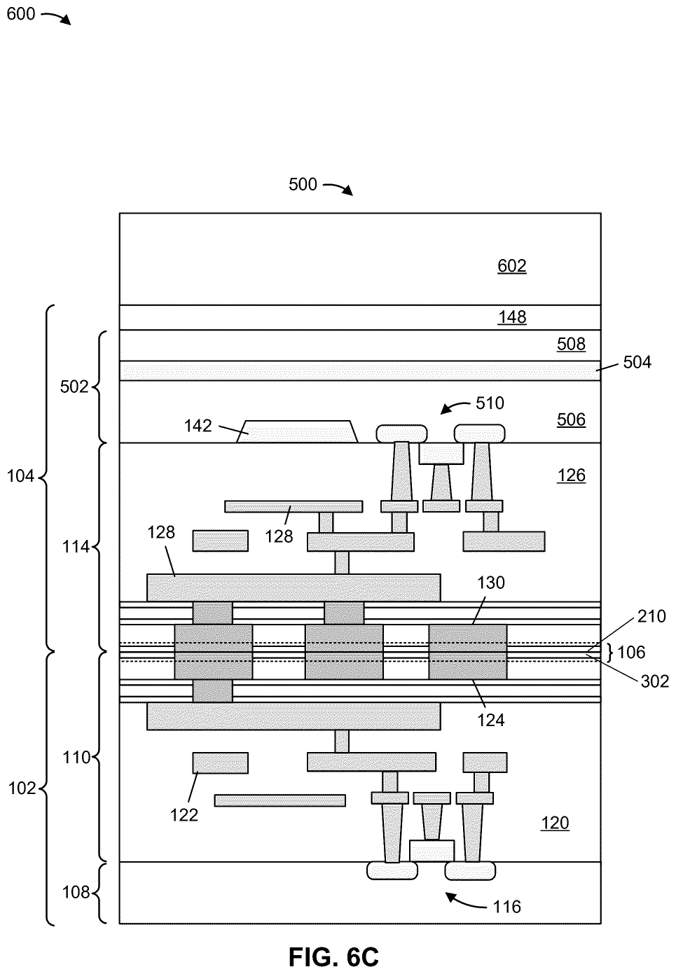

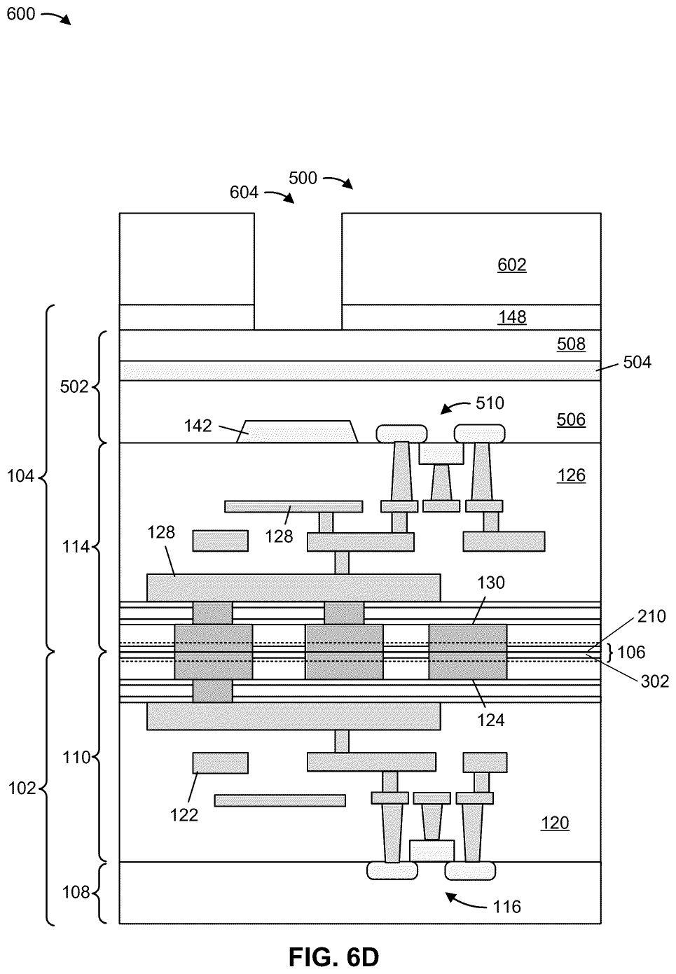

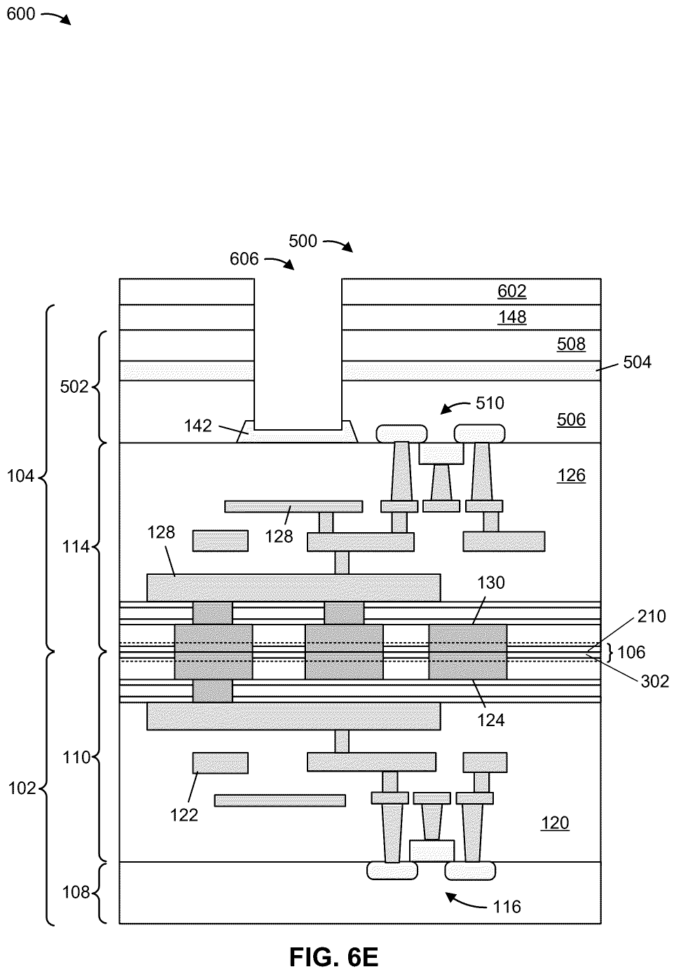

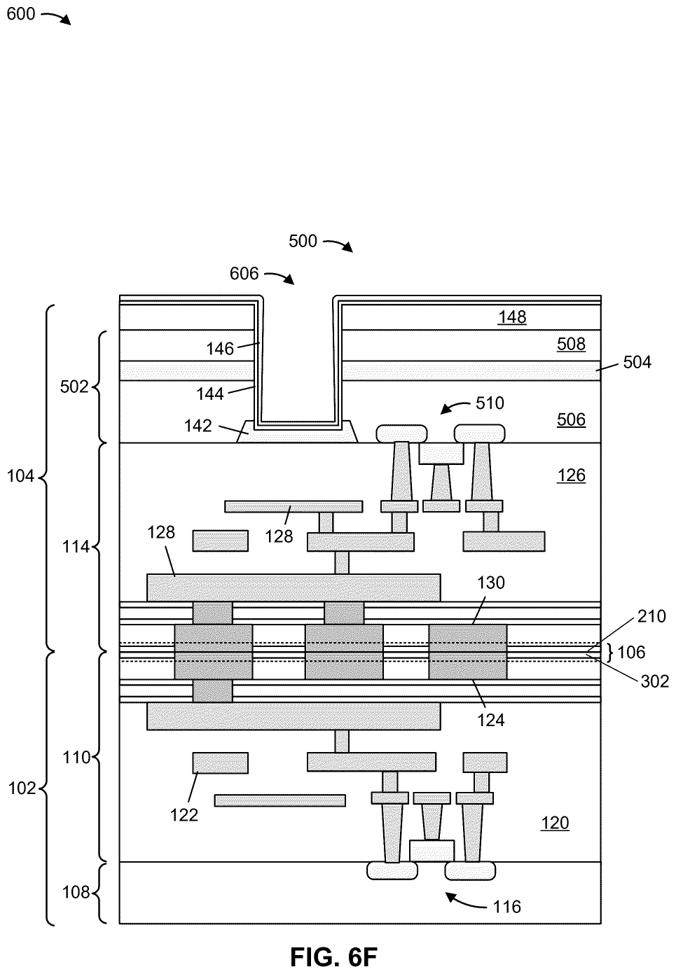

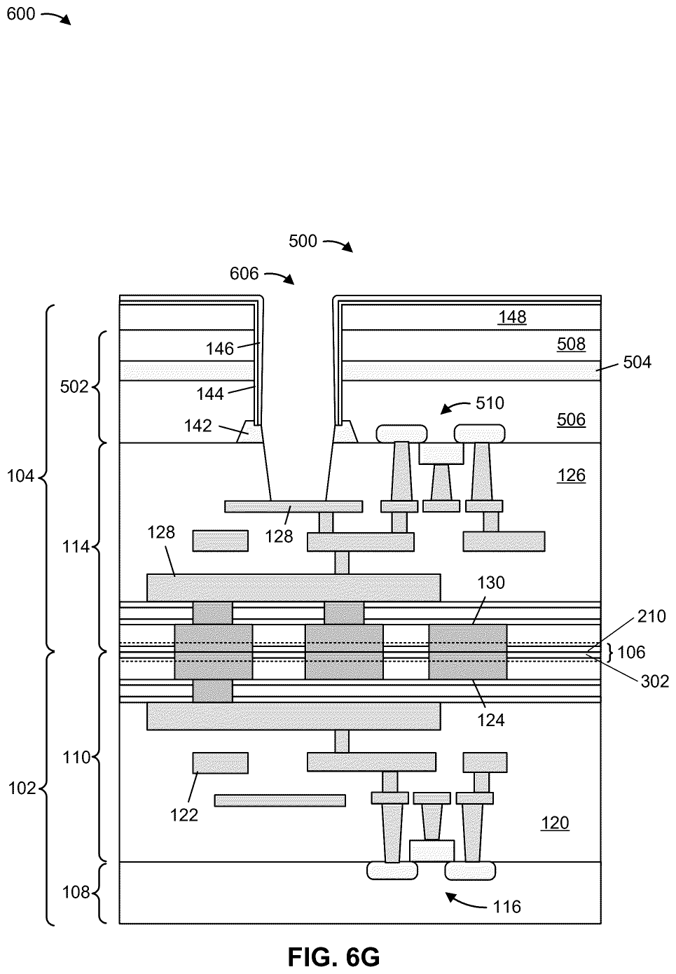

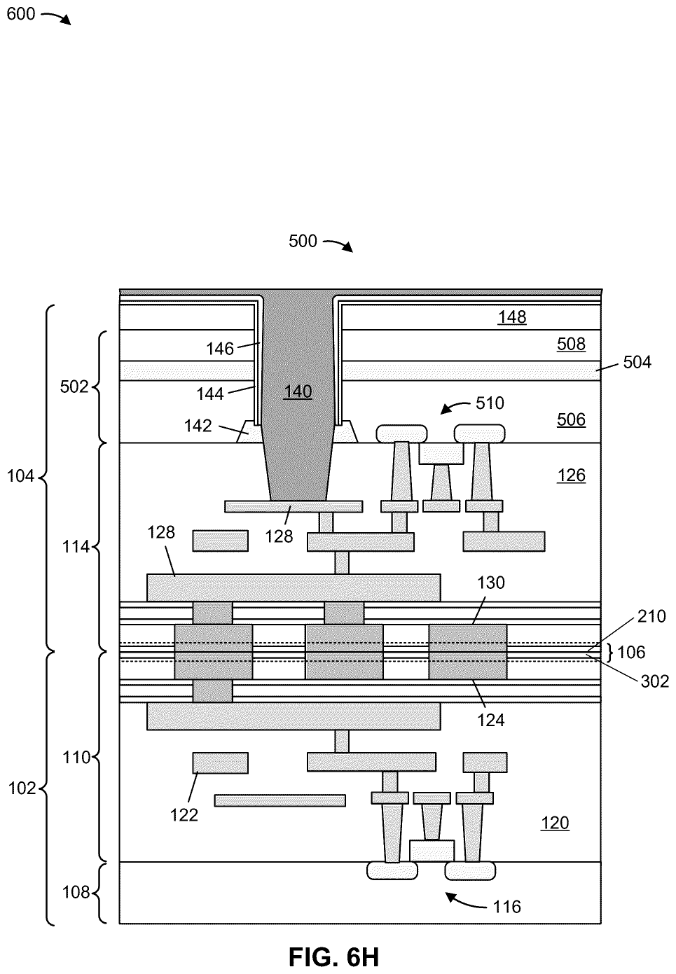

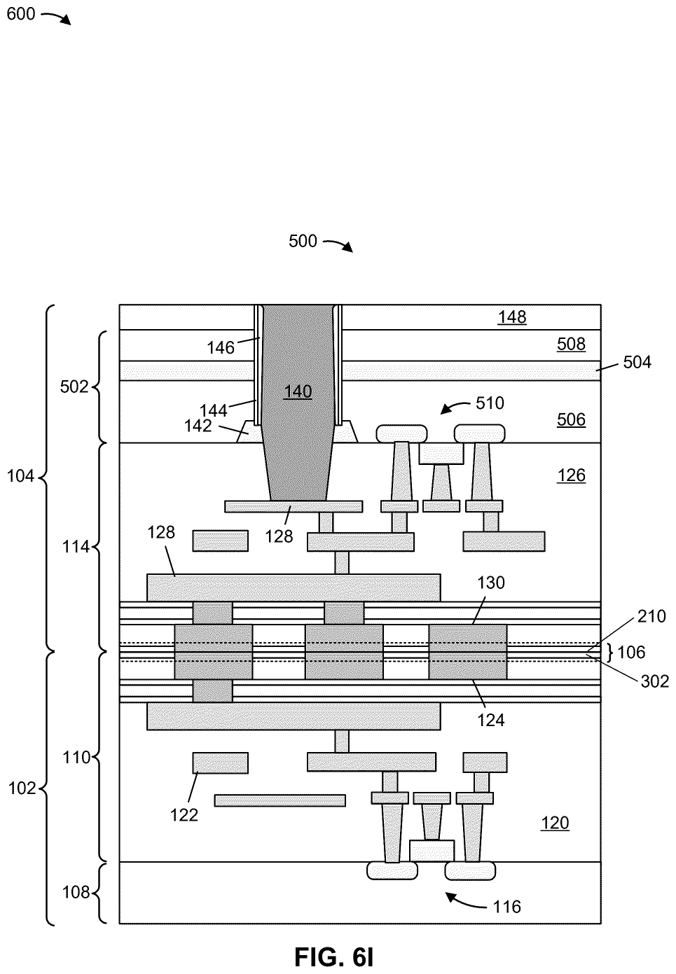

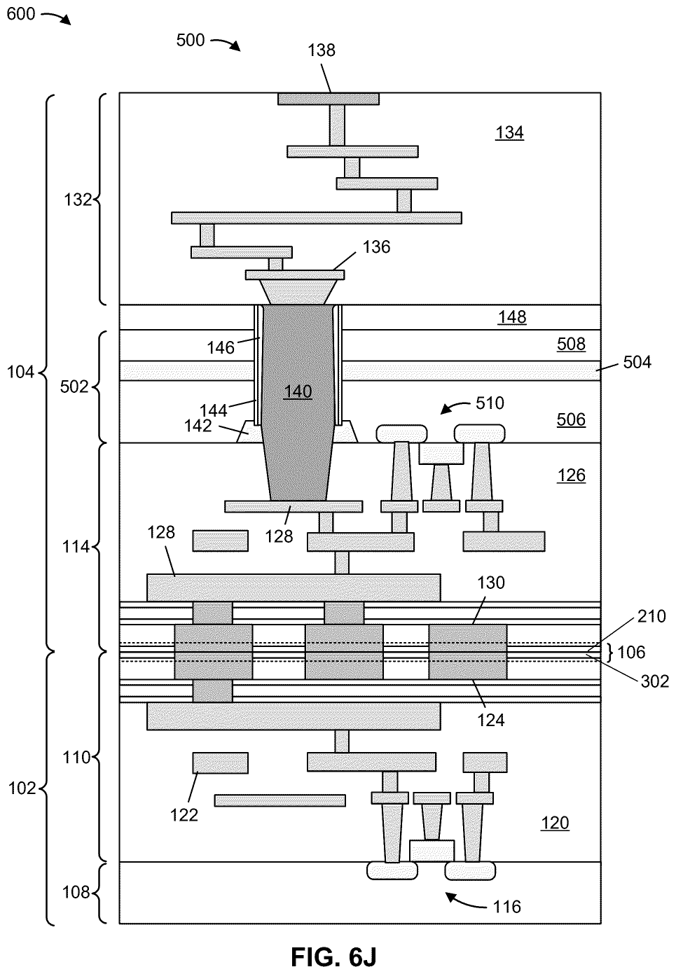

FIGS. 6A-6J are diagrams of an example implementation 600 of forming an elongated conductive structure 140 (e.g., a TSV) described herein. In some implementations, the example implementation 600 includes an example process for forming the elongated conductive structure 140 through the device layer 502 of the semiconductor die 104 included in the semiconductor die package 500. In some implementations, one or more semiconductor processing tools may be used to perform one or more of the operations described in connection with the example implementation 600, such as a deposition tool, an exposure tool, a developer tool, an etch tool, a planarization tool, a plating tool, and/or another type of semiconductor processing tool.

Turning to FIG. 6A, the semiconductor processing operations described in connection with FIGS. 6A-6J may be performed in connection with the back side of the SOI substrate of the device layer 112 of the semiconductor die 104. The semiconductor processing operations described in connection with FIGS. 6A-6J may be performed after front side processing of the semiconductor die 104, as described in connection with FIGS. 2A-2D. For example, the integrated circuit devices 510 may be formed in the first semiconductor layer 506 of the SOI substrate of the device layer 112, and the interconnect layer 114 may be formed above the front side of the SOI substrate (e.g., above the first semiconductor layer 506) of the device layer 112. Moreover, the semiconductor processing operations described in connection with FIGS. 6A-6J may be performed after bonding the semiconductor die 102 and the semiconductor die 104 to form the semiconductor die package 100 as described in connection with FIGS. 3A and 3B.

As shown in FIG. 6B, a grinding operation (e.g., a wafer grinding operation) may be performed on the back side of the SOI substrate (e.g., may be performed on the second semiconductor layer 508) of the device layer 112. A wafer grinding tool may be used to perform the grinding operation. The grinding operation may be performed to reduce the thickness of the second semiconductor layer 508 of the device layer 112 in preparation for forming one or more conductive structures 140 through the SOI substrate of the device layer 112.

As shown in FIG. 6C, the hard mask layer 148 is formed directly on the back side of the second semiconductor layer 508 of the device layer 112 after the grinding operation. Thus, the hard mask layer 148 is in direct physical contact with the second semiconductor layer 508 of the device layer 112 without an intervening passivation layer (e.g., without an intervening high-k passivation layer) between the hard mask layer 148 and the second semiconductor layer 508 of the device layer 112. As further shown in FIG. 6C, a photoresist layer 602 may be formed over and/or on the hard mask layer 148. In some implementations, a deposition tool may be used to deposit the photoresist layer 602 using a spin-coating technique and/or another suitable deposition technique.

As shown in FIG. 6D, the photoresist layer 602 may be used to form a pattern 604 in the hard mask layer 148. An exposure tool may be used to expose the photoresist layer 602 to a radiation source to form the pattern 604 the photoresist layer 602. A developer tool may be used to develop and remove portions of the photoresist layer 602 to expose the pattern 604. An etch tool may be used to etch the hard mask layer 148 based on the pattern 604 to transfer the pattern 604 to the hard mask layer 148. In some implementations, the etch operation includes a dry etch operation (e.g., a plasma-based etch operation, a gas-based etch operation), a wet chemical etch operation, and/or another type of etch operation.

As shown in FIG. 6E, a first etch operation is performed to form a recess 606 in the SOI substate of the device layer 112 based on the pattern 604 in the photoresist layer 602 and in the hard mask layer 148. The recess 406 may be formed through the second semiconductor layer 508, through the buried oxide layer 504, and into the first semiconductor layer 506 of the SOI substrate of the device layer 112 from the back side of the SOI substrate. In some implementations, the first etch operation stops on the STI region 142 in the first semiconductor layer 506 of the device layer 112. In some implementations, some over-etching occurs, and the recess 406 partially extends into the STI region 142.

As shown in FIG. 6F, one or more liners may be formed on the sidewalls and the bottom surface of the recess 406 after the first etch operation. The one or more liners may include a low-k dielectric liner 144 and/or a high-k dielectric liner 146, among other examples. In some implementations, the low-k dielectric liner 144 and/or the high-k dielectric liner 146 are also deposited over the back side of the SOI substrate of the device layer 112.

As shown in FIG. 6G, a second etch operation is performed to etch through the STI region 142 such that the recess 606 extends to the underlying conductive structure 128 in the interconnect layer 114. Thus, the depth of the recess 606 is increased from the first depth to a second depth during the second etch operation, and the conductive structure 128 is exposed through the recess 606 after the second etch operation. After the second etch operation, the recess 406 fully extends through the SOI substrate of the device layer 112, including through the buried oxide layer 504, through the first semiconductor layer 506, and through the second semiconductor layer 508.

As shown in FIG. 6H, an elongated conductive structure 140 may be formed in the recess 606 such that the elongated conductive structure 140 lands on the underlying conductive structure 128. The elongated conductive structure 140 fully extends through the hard mask layer 148 and the SOI substrate of the device layer 112, including through the buried oxide layer 504, through the first semiconductor layer 506, and through the second semiconductor layer 508. A deposition tool may be used to deposit the elongated conductive structure 140 using a CVD technique, a PVD technique, an ALD technique, an electroplating technique, and/or another suitable deposition technique. The elongated conductive structure 140 may be deposited in one or more deposition operations. In some implementations, a seed layer is first deposited, and the elongated conductive structure 140 is deposited on the seed layer. The seed layer may include a copper (Cu) seed layer and/or another suitable seed layer. In some implementations, additional liners (e.g., a tantalum nitride (TaN) liner) are deposited in the recess 606 prior to the seed layer.

As shown in FIG. 6I, a planarization tool is used to perform a planarization operation (e.g., a CMP operation) to planarize the elongated conductive structure 140 after the elongated conductive structure 140 is deposited. Excess material of the elongated conductive structure 140 may be removed from on otp of the hard mask layer 148 in the planarization operation. In some implementations, portions of the low-k dielectric liner 144 and the portions of the high-k dielectric liner 146 remaining on the hard mask layer 148 may be removed in the planarization operation.

As shown in FIG. 6J, the interconnect layer 132 is formed above the back side of the SOI substrate of the device layer 112 after formation of the elongated conductive structure 140. The interconnect layer 132 may be formed on the hard mask layer 148.

As indicated above, FIGS. 6A-6J are provided as an example. Other examples may differ from what is described with regard to FIGS. 6A-6J.

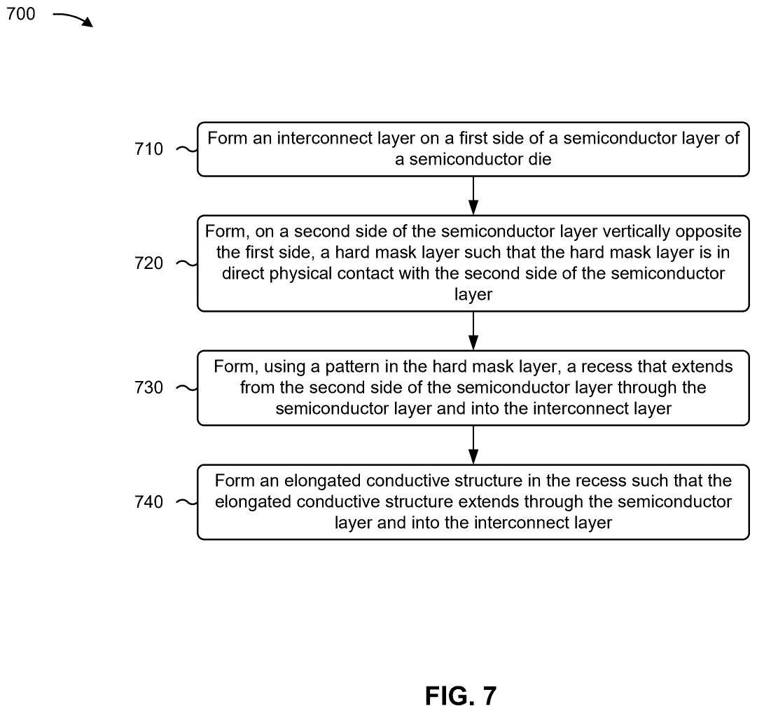

FIG. 7 is a flowchart of an example process 700 associated with forming a semiconductor die package described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming an interconnect layer on a first side of a semiconductor layer of a semiconductor die (block 710). For example, one or more semiconductor processing tools may be used to form an interconnect layer 114 on a first side (e.g., a front side) of a semiconductor layer (e.g., a device layer 112) of a semiconductor die 104, as described herein.

As further shown in FIG. 7, process 700 may include forming, on a second side of the semiconductor layer vertically opposite the first side, a hard mask layer such that the hard mask layer is in direct physical contact with the second side of the semiconductor layer (block 720). For example, one or more semiconductor processing tools may be used to form, on a second side (e.g., a back side) of the semiconductor layer (e.g., the device layer 112) vertically opposite the first side, a hard mask layer 148 such that the hard mask layer 148 is in direct physical contact with the second side of the semiconductor layer, as described herein.

As further shown in FIG. 7, process 700 may include forming, using a pattern in the hard mask layer, a recess that extends from the second side of the semiconductor layer through the semiconductor layer and into the interconnect layer (block 730). For example, one or more semiconductor processing tools may be used to form, using a pattern 404 in the hard mask layer 148, a recess 406 that extends from the second side of the semiconductor layer (e.g., the device layer 112) through the semiconductor layer and into the interconnect layer 114, as described herein.

As further shown in FIG. 7, process 700 may include forming an elongated conductive structure in the recess such that the elongated conductive structure extends through the semiconductor layer and into the interconnect layer (block 740). For example, one or more semiconductor processing tools may be used to form an elongated conductive structure 140 in the recess 406 such that the elongated conductive structure extends through the semiconductor layer (e.g., the device layer 112) and into the interconnect layer, as described herein.

Process 700 may include additional implementations, such as any single implementation or any combination of implementations described below and/or in connection with one or more other processes described elsewhere herein.

In a first implementation, process 700 includes forming one or more liners (e.g., a low-k dielectric liner 144, a high-k dielectric liner 146) on sidewalls of the recess 406, where the one or more liners are also formed on a top surface of the hard mask layer 148, and where forming the elongated conductive structure 140 includes forming the elongated conductive structure 140 such that the one or more liners are between the semiconductor layer and the elongated conductive structure 140.

In a second implementation, alone or in combination with the first implementation, forming the hard mask layer 148 includes forming the hard mask layer 148 to a thickness that is included in a range of approximately 3000 angstroms to approximately 5000 angstroms.

In a third implementation, alone or in combination with one or more of the first and second implementations, process 700 includes forming one or more passive integrated circuit devices 118 in the semiconductor layer prior to forming the interconnect layer 114.

In a fourth implementation, alone or in combination with one or more of the first through third implementations, the one or more passive integrated circuit devices 118 include one or more DTC structures.

In a fifth implementation, alone or in combination with one or more of the first through fourth implementations, the hard mask layer 148 includes a low-k dielectric material.

In a sixth implementation, alone or in combination with one or more of the first through fifth implementations, process 700 includes forming, after forming the elongated conductive structure 140, another interconnect layer 132 above the second side of the semiconductor layer.

In a seventh implementation, alone or in combination with one or more of the first through sixth implementations, process 700 includes performing a wafer grinding operation on the second side of the semiconductor layer to reduce a thickness of the semiconductor layer, where forming the hard mask layer 148 includes forming the hard mask layer 148 on the second side of the semiconductor layer after performing the wafer grinding operation.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

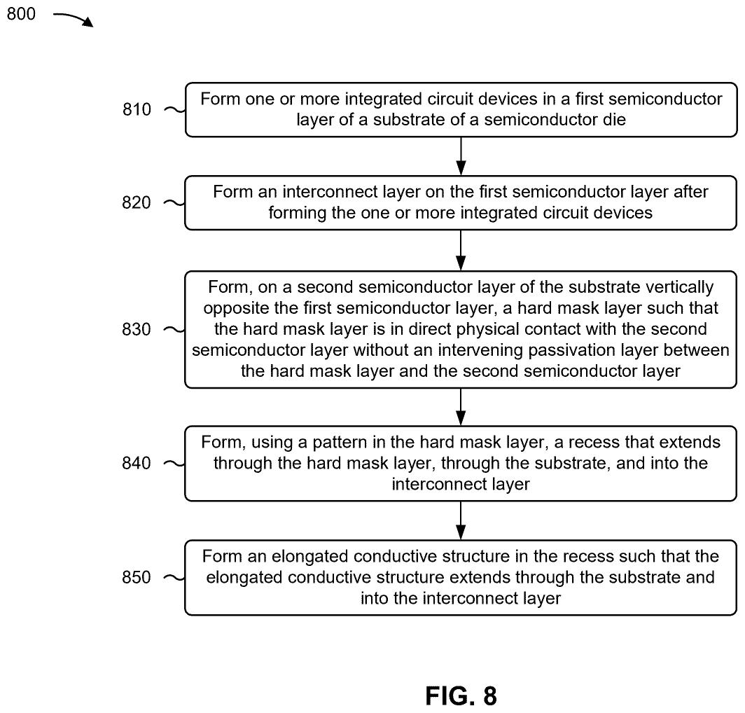

FIG. 8 is a flowchart of an example process 800 associated with forming a semiconductor die package described herein. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include forming one or more integrated circuit devices in a first semiconductor layer of a substrate of a semiconductor die (block 810). For example, one or more semiconductor processing tools may be used to form one or more integrated circuit devices 510 in a first semiconductor layer 506 of a substrate of a device layer 502 of a semiconductor die 104, as described herein.

As further shown in FIG. 8, process 800 may include forming an interconnect layer on the first semiconductor layer after forming the one or more integrated circuit devices (block 820). For example, one or more semiconductor processing tools may be used to form an interconnect layer 114 on the first semiconductor layer 506 after forming the one or more integrated circuit devices 510, as described herein.

As further shown in FIG. 8, process 800 may include forming, on a second semiconductor layer of the substrate vertically opposite the first semiconductor layer, a hard mask layer such that the hard mask layer is in direct physical contact with the second semiconductor layer without an intervening passivation layer between the hard mask layer and the second semiconductor layer (block 830). For example, one or more semiconductor processing tools may be used to form, on a second semiconductor layer 508 of the substrate of the device layer 502 vertically opposite the first semiconductor layer 506, a hard mask layer 148 such that the hard mask layer 148 is in direct physical contact with the second semiconductor layer 508 without an intervening passivation layer between the hard mask layer 148 and the second semiconductor layer 508, as described herein.

As further shown in FIG. 8, process 800 may include forming, using a pattern in the hard mask layer, a recess that extends through the hard mask layer, through the substrate, and into the interconnect layer (block 840). For example, one or more semiconductor processing tools may be used to form, using a pattern 604 in the hard mask layer 148, a recess 606 that extends through the hard mask layer 148, through the substrate of the device layer 502, and into the interconnect layer 114, as described herein.

As further shown in FIG. 8, process 800 may include forming an elongated conductive structure in the recess such that the elongated conductive structure extends through the SOI substrate and into the interconnect layer (block 850). For example, one or more semiconductor processing tools may be used to form an elongated conductive structure 140 in the recess 606 such that the elongated conductive structure 140 extends through the substrate of the device layer 502 and into the interconnect layer 114, as described herein.

Process 800 may include additional implementations, such as any single implementation or any combination of implementations described below and/or in connection with one or more other processes described elsewhere herein.

In a first implementation, process 800 includes performing a wafer grinding operation on the second semiconductor layer 508 to reduce a thickness of the second semiconductor layer 508, and forming the hard mask layer 148 includes forming the hard mask layer 148 on the second semiconductor layer 508 after performing the wafer grinding operation.

In a second implementation, alone or in combination with the first implementation, the one or more integrated circuit devices 510 include one or more transistor structures, and the substrate includes an SOI substrate in which a buried oxide layer 504 is included between the first semiconductor layer 506 and the second semiconductor layer 508.

In a third implementation, alone or in combination with one or more of the first and second implementations, the hard mask layer 148 includes at least one of a low-k oxide-containing dielectric material, an HDP oxide-containing dielectric material, an HS-USG material, or an HS-HDP oxide-containing dielectric material.

In a fourth implementation, alone or in combination with one or more of the first through third implementations, forming the hard mask layer 148 includes forming the hard mask layer 148 to a thickness that is included in a range of approximately 3000 angstroms to approximately 5000 angstroms.

In a fifth implementation, alone or in combination with one or more of the first through fourth implementations, process 800 includes bonding the interconnect layer 114 with another interconnect layer 110 of another semiconductor die 102 to form a semiconductor die package 500, where the semiconductor die 104 and the other semiconductor die 102 are vertically arranged in the semiconductor die package 500.

In a sixth implementation, alone or in combination with one or more of the first through fifth implementations, forming the hard mask layer 148 includes forming the hard mask layer 148 after bonding the interconnect layer 114 with the other interconnect layer 110.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, high-k passivation layers are omitted from a back side surface of a device layer of a semiconductor die in a semiconductor die package. Instead, a hard mask layer is formed directly on the back side surface of the device layer, and the hard mask layer is patterned and used to form one or more elongated conductive structures (e.g., one or more TSVs) through the device layer. The high-k passivation layers may be omitted for particular types of device layers and/or for particular types of integrated circuit devices, thereby reducing the complexity, time, and cost for forming the semiconductor die package.

As described in greater detail above, some implementations described herein provide a method. The method includes forming an interconnect layer on a first side of a semiconductor layer of a semiconductor die. The method includes forming, on a second side of the semiconductor layer vertically opposite the first side, a hard mask layer such that the hard mask layer is in direct physical contact with the second side of the semiconductor layer. The method includes forming, using a pattern in the hard mask layer, a recess that extends from the second side of the semiconductor layer through the semiconductor layer and into the interconnect layer. The method includes forming an elongated conductive structure in the recess such that the elongated conductive structure extends through the semiconductor layer and into the interconnect layer.

As described in greater detail above, some implementations described herein provide a method. The method includes forming one or more integrated circuit devices in a first semiconductor layer of a silicon on insulator (SOI) substrate of a semiconductor die. The method includes forming an interconnect layer on the first semiconductor layer after forming the one or more integrated circuit devices. The method includes forming, on a second semiconductor layer of the SOI substrate vertically opposite the first semiconductor layer, a hard mask layer such that the hard mask layer is in direct physical contact with the second semiconductor layer without an intervening passivation layer between the hard mask layer and the second semiconductor layer. The method includes forming, using a pattern in the hard mask layer, a recess that extends through the hard mask layer, through the SOI substrate, and into the interconnect layer. The method includes forming an elongated conductive structure in the recess such that the elongated conductive structure extends through the SOI substrate and into the interconnect layer.

As described in greater detail above, some implementations described herein provide a semiconductor die package. The semiconductor die package includes a first semiconductor die. The first semiconductor die includes a first substrate, one or more first integrated circuit devices in the first substrate, and a first interconnect layer vertically adjacent to the first substrate. The semiconductor die package includes a second semiconductor die. The second semiconductor die includes a second substrate, one or more second integrated circuit devices in the second substrate, and a second interconnect layer vertically adjacent to a front side of the second substrate. The first semiconductor die and the second semiconductor die are bonded at a bonding interface between the first interconnect layer and the second interconnect layer. The second semiconductor die includes a third interconnect layer vertically adjacent to a back side of the second substrate, and a hard mask layer between the third interconnect layer and the back side of the second substrate. The hard mask layer is in direct physical contact with the back side of the second substrate. The hard mask layer comprises a low dielectric constant (low-k) dielectric material. The second semiconductor further includes an elongated conductive structure extending through the second substrate between the front side and the back side. A top surface of the hard mask layer is approximately co-planar with a top surface of the elongated conductive structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an interconnect layer on a first side of a semiconductor layer of a semiconductor die;
forming, on a second side of the semiconductor layer vertically opposite the first side, a hard mask layer such that the hard mask layer is in direct physical contact with the second side of the semiconductor layer;
forming, using a pattern in the hard mask layer, a recess that extends from the second side of the semiconductor layer through the semiconductor layer and into the interconnect layer; and
forming an elongated conductive structure in the recess such that the elongated conductive structure extends through the semiconductor layer and into the interconnect layer.

2. The method of claim 1, further comprising:
forming one or more liners on sidewalls of the recess,
wherein the one or more liners are also formed on a top surface of the hard mask layer, and
wherein forming the elongated conductive structure comprises:
forming the elongated conductive structure such that the one or more liners are between the semiconductor layer and the elongated conductive structure.

3. The method of claim 1, wherein forming the hard mask layer comprises:
forming the hard mask layer to a thickness that is included in a range of approximately 3000 angstroms to approximately 5000 angstroms.

4. The method of claim 1, further comprising:
forming one or more passive integrated circuit devices in the semiconductor layer prior to forming the interconnect layer.

5. The method of claim 4, wherein the one or more passive integrated circuit devices comprise one or more deep trench capacitor (DTC) structures.

6. The method of claim 1, wherein the hard mask layer comprises a low dielectric constant (low-k) dielectric material.

7. The method of claim 1, further comprising:
forming, after forming the elongated conductive structure, another interconnect layer above the second side of the semiconductor layer.

8. The method of claim 1, further comprising:
performing a wafer grinding operation on the second side of the semiconductor layer to reduce a thickness of the semiconductor layer,
wherein forming the hard mask layer comprises:
forming the hard mask layer on the second side of the semiconductor layer after performing the wafer grinding operation.

9. A method, comprising:
forming one or more integrated circuit devices in a first semiconductor layer of a substrate of a semiconductor die;
forming an interconnect layer on the first semiconductor layer after forming the one or more integrated circuit devices;
forming, on a second semiconductor layer of the substrate vertically opposite the first semiconductor layer, a hard mask layer such that the hard mask layer is in direct physical contact with the second semiconductor layer without an intervening passivation layer between the hard mask layer and the second semiconductor layer;
forming, using a pattern in the hard mask layer, a recess that extends through the hard mask layer, through the substrate, and into the interconnect layer; and
forming an elongated conductive structure in the recess such that the elongated conductive structure extends through the substrate and into the interconnect layer.

10. The method of claim 9, further comprising:
performing a wafer grinding operation on the second semiconductor layer to reduce a thickness of the second semiconductor layer,
wherein forming the hard mask layer comprises:
forming the hard mask layer on the second semiconductor layer after performing the wafer grinding operation.

11. The method of claim 9, wherein the one or more integrated circuit devices comprise one or more transistor structures; and
wherein the substrate comprises a silicon on insulator (SOI) substrate that includes a buried oxide layer between the first semiconductor layer and the second semiconductor layer.

12. The method of claim 9, wherein the hard mask layer comprises at least one of:
a low dielectric constant (low-k) oxide-containing dielectric material,
a high-density plasma (HDP) oxide-containing dielectric material,
a high-stress undoped silicate glass (HS-USG) material, or
a high-stress HDP (HS-HDP) oxide-containing dielectric material.

13. The method of claim 9, wherein forming the hard mask layer comprises:
forming the hard mask layer to a thickness that is included in a range of approximately 3000 angstroms to approximately 5000 angstroms.

14. The method of claim 9, further comprising:
bonding the interconnect layer with another interconnect layer of another semiconductor die to form a semiconductor die package,
wherein the semiconductor die and the other semiconductor die are vertically arranged in the semiconductor die package.

15. The method of claim 14, wherein forming the hard mask layer comprises forming the hard mask layer after bonding the interconnect layer with the other interconnect layer.

16. A semiconductor die package, comprising:
a first semiconductor die, comprising:
a first substrate;
one or more first integrated circuit devices in the first substrate;
a first interconnect layer vertically adjacent to the first substrate; and
a second semiconductor die, comprising:
a second substrate;
one or more second integrated circuit devices in the second substrate;
a second interconnect layer vertically adjacent to a front side of the second substrate,
wherein the first semiconductor die and the second semiconductor die are bonded at a bonding interface between the first interconnect layer and the second interconnect layer;
a third interconnect layer vertically adjacent to a back side of the second substrate;
a hard mask layer between the third interconnect layer and the back side of the second substrate,
wherein the hard mask layer is in direct physical contact with the back side of the second substrate, and
wherein the hard mask layer comprises a low dielectric constant (low-k) dielectric material; and
an elongated conductive structure extending through the second substrate between the front side and the back side,
wherein a top surface of the hard mask layer is approximately co-planar with a top surface of the elongated conductive structure.

17. The semiconductor die package of claim 16, wherein the elongated conductive structure is electrically coupled at a first end of the elongated conductive structure with a first conductive structure in the second interconnect layer; and
wherein the elongated conductive structure is electrically coupled at a first end of the elongated conductive structure with a second conductive structure in the third interconnect layer.

18. The semiconductor die package of claim 16, wherein the second substrate comprises a silicon (Si) substrate; and
wherein the one or more second integrated circuit devices comprise one or more passive integrated circuit devices.

19. The semiconductor die package of claim 16, wherein the second substrate comprises a silicon on insulator (SOI) substrate; and
wherein the one or more second integrated circuit devices comprise one or more active integrated circuit devices.

20. The semiconductor die package of claim 19, wherein the second interconnect layer is vertically adjacent to a first semiconductor layer of the SOI substrate;
wherein the hard mask layer is in direct physical contact with a second semiconductor layer of the SOI substrate; and
wherein the first semiconductor layer and the second semiconductor layer are physically separated by a dielectric layer.
